(19) United States
(12) Patent Application Publication
(10) Pub. No.: US 2008/0299771 A1
(43) Pub. Date: Dec. 4, 2008

(54) METHODS OF MAKING THIN FILM TRANSISTORS COMPRISING ZINC-OXIDE-BASED SEMICONDUCTOR MATERIALS AND TRANSISTORS MADE THEREBY

(76) Inventors: Lyn M. Irving, Rochester, NY (US); David H. Levy, Rochester, NY (US); Andrea C. Childs, Webster, NY (US)

Correspondence Address: Andrew J. Anderson;Patent Legal Staff, Eastman Kodak Company, 343 State Street, Rochester, NY, 14650-2201, US

(21) Appl. No.: 11/757,633

(22) Filed: Jun. 4, 2007

(51) Int. Cl. H01L 21/44; H01L 29/08

(52) U.S. Cl. 438/681; 257/72; 257/E29.029; 257/E21.476

(57) ABSTRACT

A method of making a thin film transistor comprising a thin film semiconductor element comprised of a transparent zinc-oxide-based semiconductor material, wherein spaced apart first and second contacts in contact with said material are position on either side of a channel in the thin film semiconductor element such that the elongated sides of the channel are aligned with an underlying gate structure. The method can be accomplished while maintaining the substrate temperature at no more than 300° C. during fabrication.

### FIELD OF THE INVENTION

The present invention relates to a method of making thin film transistors comprising zinc-oxide-based semiconductor materials. Such thin film transistors can be used in electronic devices, particularly in flexible displays.

### BACKGROUND OF THE INVENTION

For applications in which a transistor needs to be applied to a substrate, a thin film transistor is typically used. Thin film transistors (TFTs) are widely used as switching elements in electronics, for example, in active-matrix liquid-crystal displays, smart cards, and a variety of other electronic devices and components thereof. The thin film transistor (TFT) is an example of a field effect transistor (FET). The best-known example of an FET is the MOSFET (Metal-Oxide-Semiconductor-FET), today's conventional switching element for high-speed applications.

A critical step in fabricating the thin film transistor involves the deposition of a semiconductor onto the substrate. Presently, most thin film devices are made using vacuum deposited amorphous silicon as the semiconductor. However, the deposition of amorphous silicon, during the manufacture of transistors, requires relatively difficult or complicated processes such as plasma enhanced chemical vapor deposition and high temperatures (about 360° C.) to achieve the electrical characteristics sufficient for display applications. Such high processing temperatures disallow deposition on substrates made of certain plastics that might otherwise be desirable for use in certain applications such as flexible displays.

In the past decade, various materials have received attention as a potential alternative to amorphous silicon for use in semiconductor channels of thin film transistors. Semiconductor materials that are simpler to process are desirable. Also desirable are semiconductors that are capable of being applied to large areas by a relatively simple process or those that are amenable to a roll-to-roll process. Furthermore, additive processes have the opportunity to reduce materials costs by only applying semiconductor materials where they are needed.

Semiconductor materials that can be deposited at lower temperatures would open up a wider range of substrate materials. Thin film transistors that can be economically formed on a flexible substrate can be viewed as a potentially important technology for circuitry in various electronic devices or components such as display backplanes, portable computers, pagers, memory elements in transaction cards, and identification tags, where ease of fabrication and mechanical flexibility are advantageous.

New semiconductor materials that are compatible with temperature-sensitive or flexible substrates and that have electronic properties equivalent to amorphous silicon have also been the subject of considerable research efforts. For example, metal oxide semiconductors are known that constitute zinc oxide, indium oxide, tin oxide, cadmium oxide, or combinations thereof, deposited with or without additional doping elements including transition metals such as aluminum. Such semiconductor materials, which are transparent, are especially useful in the fabrication of transparent thin film transistors. Such transparent transistors can be advantageously used to control pixels in a display. By being transparent, the active area of the transistor can be significantly increased.

For example, thin film transistors are employed in active-matrix liquid crystal displays (AMLCD), which are extensively used in laptop computers and other information display products. The operation of an AMLCD display requires that each picture or display element (pixel) have a corresponding thin film transistor associated with it for selecting or addressing the pixel to be on or off (“pixel driver”). Presently, AMLCD displays employ transistor materials that may be deposited onto glass substrates but are not transparent (typically amorphous, polycrystalline, or continuous-grain silicon deposited on glass). The portion of the display glass occupied by the addressing electronics is not available for transmission of light through the display. Transparent thin film transistors for AMLCD addressing would allow greater light transmission through the display, thereby improving display performance.

Transparent conducting oxides are reviewed in the August 2000 issue of the Materials Research Bulletin, Volume 25 (8) 2000, devoted to materials and properties of transparent conducting oxide compounds.

Accordingly, there is a growing interest in depositing thin film semiconductors on plastic or flexible substrates, particularly because these supports would be more mechanically robust, lighter weight, and potentially lead to cheaper manufacturing by allowing roll-to-roll processing. A useful example of a flexible substrate is polyethylene terephthalate (PET) or polyethylene naphthalate (PEN). Such plastics, however, limit device processing to below 200° C.

In spite of the potential advantages of flexible substrates, there are many issues affecting the performance and ability to perform alignments of transistor components across typical substrate widths up to one meter or more.

The overlay accuracy achievable using traditional photolithography equipment can be seriously impacted by maximum process temperature, solvent resistance, dimensional stability, water and solvent swelling, all key parameters in which plastic supports are typically inferior to glass.

In TFT fabrication, there is typically needed highly accurate alignment of the gate electrode with the source and drain electrode, which can cause problems. Usually, the source and drain electrodes of all TFTs on a substrate are aligned globally using alignment marks. Such patterning is difficult, manufacturing processes are complicated, and huge facilities are required for the processes, resulting in high costs. Further, the equipment for sequential layer alignment has limited accuracy, leading to some misalignment offset of the gate electrode with the source and drain electrodes.

Because the source-drain contacts are not self-aligned, the degree of overlap with the gate electrode is usually increased to allow for the misalignment offsets. This is undesirable because it increases the source-drain to gate capacitance of the devices, which in turn increases the pixel feedthrough voltage (ΔVp) in the active matrix display. The feedthrough voltage is caused by charge stored in the TFT source to gate capacitance when the pixel TFT has charged the pixel and returns to its OFF state. The ΔVp offset must be compensated for using a combination of passive elements (storage capacitors) included in the active matrix design and suitable electronic drive schemes.

Further, if the substrate expands or shrinks during the fabrication process, an overlay scale error is introduced to the set of TFTs which could result in a shift in Source/Drain (S/D) alignment across the active matrix. This alignment shift may lead to incomplete compensation of ΔVp and hence to visual artifacts in the finished display.

Further, there is a problem that characteristics of transistors are often damaged or subject to deterioration by solvents and the like used in fabrication processes, for example, solvents in a developer solution used for lithography succeeding the formation of a semiconductor layer.

Thus, although simplified processes have been proposed, there are problems that the fabrication method can adversely affect various properties such as carrier mobility, gate voltage, electric current value under the state of switching-on, and ON/OFF value of an electric current.

Various methods have been proposed for defining self-aligned amorphous silicon TFTs where the gate electrode is used as a mask to protect the channel area from doping and laser annealing of the silicon layer on either side of the channel area. For example, US Patent Application Publication No. 2004/0229411 A1, describes forming doped silicon source and drain regions and employing the gate electrode to shield the channel region in a subsequent laser annealing process.

US Patent Application Publication No. 2004/0266207A1 describes creating surface energy patterns to direct position and flow of ink droplets of electroactive polymers to build printed organic transistor structures.

US Patent Application Publication No. 2005/0051780A1 describes fabrication of organic TFTs employing a self-assembled monolayer (SAM) deposited on top of the gate insulator. The SAM is subsequently patterned in the TFT channel region in vertical alignment with the gate electrode. Improved organic TFTs are produced by this method, because the SAM selectively improves the orientation order of the organic semiconductor in the TFT channel region.

The present invention facilitates, in the fabrication of transparent metal-oxide thin film transistors, accurate alignment of the source and drain with respect to the gate, in a simple way, which transistors can be manufactured at relatively low temperatures on flexible substrates. Thus, the aforesaid problems are greatly solved.

### SUMMARY OF THE INVENTION

To overcome the abovementioned drawbacks in conventional zinc oxide thin-film transistors and conventional methods for manufacturing them, it is an object of the present invention to provide a zinc-oxide-based thin-film transistor, which is manufactured by an accurate patterning process at low cost without requiring complicated manufacturing processes.

Accordingly, to overcome the cited shortcomings, the above-mentioned objects of the present invention can be attained by a method of making zinc oxide thin-film transistors supported on a substrate having a first side and a second side, wherein the substrate is substantially transmissive to a pre-selected spectrum of actinic radiation, wherein the method comprises:
(a) depositing on the first side of the substrate a non-transmissive first conductive material to form a non-transmissive gate structure that is substantially not transmissive to said pre-selected spectrum of actinic radiation;
(b) depositing over the gate structure dielectric material to form a dielectric layer;
(c) depositing transparent zinc-oxide-based semiconductor material over the dielectric layer, vertically spaced from the non-transmissive gate structure by the dielectric layer;
(d) applying a layer of positive-working photoresist material over the first side of the substrate, over the semiconductor thin film, and then exposing the photoresist material to said pre-selected spectrum of actinic radiation from a source thereof through the second side of the substrate, wherein the non-transmissive gate structure masks the actinic radiation, thereby forming an exposed area of photoresist material not blocked by the non-transmissive gate structure;
(e) developing the exposed photoresist to form a patterned passivation structure comprising parallel elongated walls vertically aligned with parallel elongated sides of the gate structure;
(f) depositing a second conductive material to form a source electrode and drain electrode, wherein the source electrode and the drain electrode are positioned over, and in electrical contact with, the semiconductor thin film and horizontally separated from each other by a spacing provided by the passivation structure; and
(g) patterning the transparent zinc-oxide semiconductor material to form a semiconductor thin film element in which said spacing provided by the passivation structure dimensionally defines a channel in the semiconductor thin film element that is aligned with the gate structure, wherein the semiconductor channel comprises parallel elongated sides that are aligned with the parallel elongated sides of the gate structure via the alignment with the elongated parallel walls of the passivation structure.

In the case of a plurality of transistors, step (a) can comprise depositing and patterning, on a substrate substantially transmissive to a preselected spectrum of actinic radiation, a gate-electrode material to form a gate-electrode structure having first and second elongated sides diverging from a bus line.

The invention is also directed to a transistor comprising a zinc-oxide-based semiconductor, preferably on a flexible substrate, made by the present process.

Semiconductor films made by the present method are capable of exhibiting, in the film form, stable threshold voltages and excellent field-effect electron mobility of greater than 0.01 cm²/Vs and on-off ratios of greater than 10⁴, in which performance properties are sufficient for use in a variety of relevant technologies, including active matrix display backplanes.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical or analogous features that are common to the figures, and wherein:

FIG. 1A and FIG. 1B, in which FIG. 1B is a cross-section of the structure of FIG. 1A, shows Step (a) of one embodiment of the present process, in which a gate material is deposited and patterned;

FIG. 2A and FIG. 2B, in which FIG. 2B is a cross-section of the structure of FIG. 2A, shows Step (b) of one embodiment of the present process, in which a dielectric material is deposited

FIG. 3A and FIG. 3B, in which FIG. 3B is a cross-section of the structure of FIG. 3A, shows Step (c) of one embodiment of the present process, in which a semiconductor material is deposited;

FIG. 4A and FIG. 4B, in which FIG. 4B is a cross-section of the structure of FIG. 4A, shows Step (d) of one embodiment of the present process, in which a pattern of unexposed photopatternable material is deposited selectively and exposed from the support side to produce a non-continuous pattern of photoresist;

FIG. 5A and FIG. 5B, in which FIG. 5B is a cross-section of the structure of FIG. 5A, shows Step (e) of one embodiment of the present process, in which the photoexposed material is developed to form a fluid barrier aligned with the previously formed gate structure;

FIG. 6A and FIG. 6B, in which FIG. 6B is a cross-section of the structure of FIG. 6A, shows Step (f) of one embodiment of the present process, in which a source and drain is printed;

FIG. 7A and FIG. 7B, in which FIG. 7B is a cross-section of the structure of FIG. 7A, shows Step (g) of a second embodiment of the present process, in which semiconductor material is removed in order to form a thin film semiconductor element;

FIG. 8A and FIG. 8B, in which FIG. 8B is a cross-section of the structure of FIG. 8A, shows Step (a) of a second embodiment of the present process, in which a gate material is deposited and patterned along with electrically isolated internal photomask patterns;

FIG. 9A and FIG. 9B, in which FIG. 9B is a cross-section of the structure of FIG. 9A, shows Step (e) of a second embodiment of the present process, in which a photoexposed photoresist material is patterned to form outer containment elements, for the source and drain, that are aligned with the internal photomask patterns of FIG. 8A;

FIG. 10A and FIG. 10B, in which FIG. 10B is a cross-section of the structure of FIG. 10A, shows Step (f) of a second embodiment of the present process, in which a source and drain electrode is printed in to a multisided containment structure;

FIG. 11A and FIG. 11B, in which FIG. 11B is a cross-section of the structure of FIG. 11A, shows Step (g) of a second embodiment of the present process, in which the semiconductor layer is patterned to form a thin film semiconductor element;

FIGS. 12A, 12B, and 12C in which FIG. 12B is a cross-section of the structure of FIG. 12A and FIG. 12C is a planar view of the photomask shown in FIG. 12B, shows Step (g) of a third embodiment of the present process, in which a photopatternable photoresist layer is exposed from the support side through a relatively low resolution photomask;

FIG. 13A and FIG. 13, in which FIG. 13B is a cross-section of the structure of FIG. 13A, shows Step (f) of a third embodiment of the present process, in which a source and drain electrode material is printed into a containment structure that is formed in the photoresist layer using the photomask of FIG. 12C;

FIG. 14A and FIG. 14B, in which FIG. 14B is a cross-section of the structure of FIG. 14A, shows Step (g) of a third embodiment of the present process, in which the semiconductor layer is patterned to form a thin film semiconductor element;

FIG. 15 shows a process flow diagram summarizing the above-described embodiments of the present invention;

FIG. 16 illustrates a typical active matrix pixel design comprising a select transistor and capacitor representing the capacitance due to display design; and

FIG. 17 illustrates a typical pixel layout comprising data lines, control lines, thin film transistors, and pixel conductor pads.

### DETAILED DESCRIPTION OF THE INVENTION

As indicated above, the present invention is directed to a method of making a thin film transistor comprising a zinc-oxide-based semiconductor. Preferred semiconductors are zinc-oxide-based materials that are capable of yielding a high mobility, low carrier concentration, and high band gap.

A thin film transistor made by the present invention typically comprises spaced apart first and second contact means connected to a semiconductor film. A third contact means can be spaced from said semiconductor film by an insulator, and adapted for controlling, by means of a voltage applied to the third contact means, a current between the first and second contact means through said film. The first, second, and third contact means can correspond to a drain, source, and gate electrode in a field effect transistor.

For ease of understanding, the following terms used herein are described below in more detail:

“Enhancement-mode transistor” means a transistor in which there is negligible off-current flow, relative to on-current flow, between a source and a drain at zero gate voltage. In other words, the transistor device is “normally off.” In contrast, a depletion-mode transistor is “normally on” meaning that more than a substantially negligible current flows between a source and a drain at zero gate voltage. Enhancement is typically preferred.

“Gate” generally refers to the insulated gate terminal of a three terminal FET when used in the context of a transistor circuit configuration.

“Substantially transparent” generally denotes a material or construct that allows a substantial amount of radiation in the pre-selected spectrum of actinic radiation to pass through the substrate supporting the gate of a thin film transistor. The pre-selected spectrum can be visible light and/or the infrared portion and/or ultraviolet portion, depending on the embodiment. “Actinic radiation” is defined herewith to mean electromagnetic radiation that is capable of causing a chemical change, for example, a photochemical change in a photoresist.

As used herein, “a” or “an” or “the” are used interchangeably with “at least one,” to mean “one or more” of the element being modified.

As used herein, the terms “over,” “above,” and “under” and the like, with respect to layers in the thin film transistor, refer to the order of the layers, wherein the thin film semiconductor layer is above the gate electrode, but do not necessarily indicate that the layers are immediately adjacent or that there are no intermediate layers.

The preceding term descriptions are provided solely to aid the reader, and should not be construed to have a scope less than that understood by a person of ordinary skill in the art or as limiting the scope of the appended claims.

An illustrative n-channel operation of the transistor involves applying a positive voltage to the gate electrode, grounding the source, and applying a positive voltage to the drain. For example, a voltage of about 5 to about 40 V may be applied to the gate electrode and the drain during operation. The threshold voltage may range from about minus 10 to about 20 V, although devices can operate with larger ranges. Electrons flow from the source, along the semiconductor thin film, and out of the transistor through the drain. The effective mobility of the electrons may vary depending upon the specific structure, but typically should be greater than 0.01 cm²V⁻¹s⁻¹ for useful practical applications. Simply by removing the positive voltage applied to the gate electrode turns the transistor off when the transistor is an enhancement-mode transistor.

In the operation of a TFT device, a voltage applied between the source and drain electrodes establishes a substantial current flow only when the control gate electrode is energized. That is, the flow of current between the source and drain electrodes is modulated or controlled by the bias voltage applied to the gate electrode. The relationship between material and device parameters of the zinc-oxide-based semiconductor TFT can be expressed by the approximate equation (see Sze in Semiconductor Devices—Physics and Technology, John Wiley & Sons (1981)):

$${I}_{d} = \frac{W}{2 L} μ {C ( {V}_{g} - {V}_{th} )}^{2}$$

where I_{d} is the saturation source-drain current, C is the geometric gate capacitance, associated with the insulating layer, W and L are physical device dimensions, μ is the carrier (hole or electron) mobility in the zinc-oxide-based semiconductor, and V_{g} is the applied gate voltage, and Vₜₕ is the threshold voltage. Ideally, the TFT allows passage of current only when a gate voltage of appropriate polarity is applied. However, with zero gate voltage, the “off” current between source and drain will depend on the intrinsic conductivity σ of the zinc-oxide-based semiconductor,

σ=nqμ

where n is the charge carrier density and q is the charge, so that

(I_{sd})=σ(Wt/L)V_{sd}@ Vg=0

wherein t is the zinc-oxide-based semiconductor layer thickness and V_{sd} is the voltage applied between source and drain. Therefore, for the TFT to operate as a good electronic switch, e.g. in a display, with a high on/off current ratio, the semiconductor needs to have high carrier mobility but very small intrinsic conductivity, or equivalently, a low charge carrier density. On/off ratios >10⁴ are desirable for practical devices.

One embodiment of the present method comprises depositing transparent zinc-oxide-based semiconductor material over a dielectric layer, vertically spaced from the non-transmissive gate structure by the dielectric layer and then applying a layer of the positive-working photoresist material over the first side of the substrate, over the semiconductor thin film. The photoresist material is then exposed to a pre-selected spectrum of actinic radiation from a source thereof through the opposite side of the substrate from the semiconductor material, wherein the non-transmissive gate structure masks the actinic radiation, thereby forming an exposed area of photoresist material not blocked by the non-transmissive gate structure. The exposed photoresist is then developed to form a patterned passivation structure comprising parallel elongated walls vertically aligned with parallel elongated sides of the gate structure. Next, a second conductive material is deposited to form a source electrode and drain electrode, wherein the source electrode and the drain electrode are positioned over, and in electrical contact with, the semiconductor thin film and horizontally separated from each other by a spacing provided by the passivation structure. Finally, the transparent zinc-oxide semiconductor material is patterned to form a semiconductor thin film element in which the spacing provided by the passivation structure dimensionally defines a channel in the semiconductor thin film element that is aligned with the gate structure. Accordingly, the semiconductor channel comprises parallel elongated sides that are aligned with the parallel elongated sides of the gate structure via the alignment with the elongated parallel walls of the passivation structure.

Preferably, the temperature of the substrate during the present method is 200° C. or less. The substrate used for supporting the TFT during manufacturing and use, in some embodiments, does not provide any necessary electrical function for the TFT. This type of support is termed a “non-participating support” in this document. Useful materials can include substantially transparent organic or inorganic materials. For example, the support may comprise inorganic glasses, polymeric materials, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(ether sulfone) (PES), poly(phenylene sulfide) (PPS), and fiber-reinforced plastics (FRP). More preferable support materials include PEN and PET.

A flexible support is used in some embodiments. This allows for roll processing, which may be continuous, providing economy of scale and economy of manufacturing over flat and/or rigid supports. The flexible support chosen preferably is capable of wrapping around the circumference of a cylinder of less than about 50 cm diameter, more preferably 25 cm diameter, most preferably 10 cm diameter, without distorting or breaking, using low force as by unaided hands. The preferred flexible support may be rolled upon itself.

If flexibility is not a concern, then the substrate may be a wafer or sheet made of materials including glass.

The thickness of the substrate may vary, and according to particular examples it can range from about 20 μm to about 1 cm.

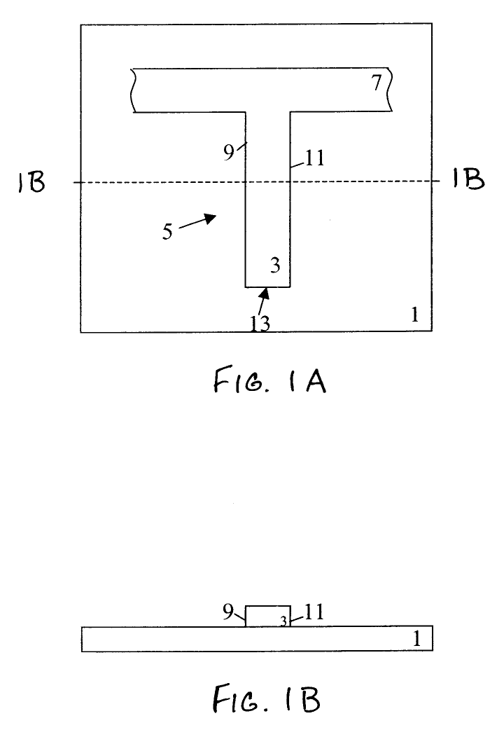

Referring now to FIG. 1A and FIG. 1B, wherein FIG. 1B taken along line 1B-1B of FIG. 1A, Step (a) of the process is illustrated, involving formation of a gate structure (electrode), preferably a metal, on a support or substrate 1. Step (a) involves depositing and patterning a layer of conductive material on substrate 1 to form a patterned gate-bus structure 5 comprising gate electrode 3 and bus line 7, in the case of a plurality of gate structures along a common bus line 7. The bus line 7 can be connected to additional gate electrodes (not shown) along the continuation of bus line 7 on the substrate 1. The gate material can be simultaneously or sequentially deposited and patterned by various methods. For example, a metal can be evaporated using shadow mask to form a patterned structure. Alternately, a conductive coating can be applied, followed by photolithographic etching to form a patterned conductive structure. Still another method involves a photolithographic lift-off process, in which a conductive coating is applied over a pre formed photoresist pattern, then the photoresist is removed to lift off the conductive areas that were located on top. Still another method of forming the gate-bus structure 5 involves applying a conductive material in the form of a fluid composition by inkjet printing (usually followed by annealing), thereby forming a patterned structure. For example, a fluid composition comprising silver nanoparticles in a solvent can be applied to the substrate and subsequently dried, optionally with annealing or other treatment to activate the conductive material. In another embodiment, the gate-bus structure 5 is formed by evaporatively depositing chrome metal through a shadow mask. Still another method involves adhesion transfer of a patterned conductive structure from a transfer material, for example, a composite multilayer structure, to the substrate 1.

In the embodiment of FIGS. 1A and 1B, the gate-bus structure 5 comprises a gate electrode 3 in the form of a peninsula, formed by three sides of a rectangle, that diverges substantially perpendicularly from the bus line 7. Thus, the gate electrode 3 in FIGS. 1A and 1B comprises first and second elongated sides 9 and 11 and terminal end 13.

The gate electrode can be made of any useful conductive material which blocks or attenuates actinic radiation used to create the passivation structure. A variety of gate materials known in the art, are also suitable, including metals, degenerately doped semiconductors, conducting polymers, and printable materials such as carbon ink, silver-epoxy, or sinterable metal nanoparticle suspensions. For example, the gate electrode may comprise doped silicon, or a metal, such as aluminum, chromium, gold, silver, nickel, copper, tungsten, palladium, platinum, tantalum, and titanium. In an alternative embodiment, the gate material may be colored to allow selective transmission of a preselected spectrum of actinic radiation. Conductive polymers also can be used, for example polyaniline, poly(3,4-ethylenedioxythiophene)/poly(styrene sulfonate) (PEDOT:PSS). In addition, alloys, combinations, and multilayers of these materials may be useful.

The thickness of the gate electrode may vary, and according to particular examples it can range from about 50 to about 1000 nm. The gate electrode may be introduced into the structure by chemical vapor deposition, sputtering, evaporation and/or doping, or solution processing.

In some embodiments, the same material can provide the gate electrode function and also provide the support function of the support. For example, doped silicon can function as the gate electrode and support the TFT.

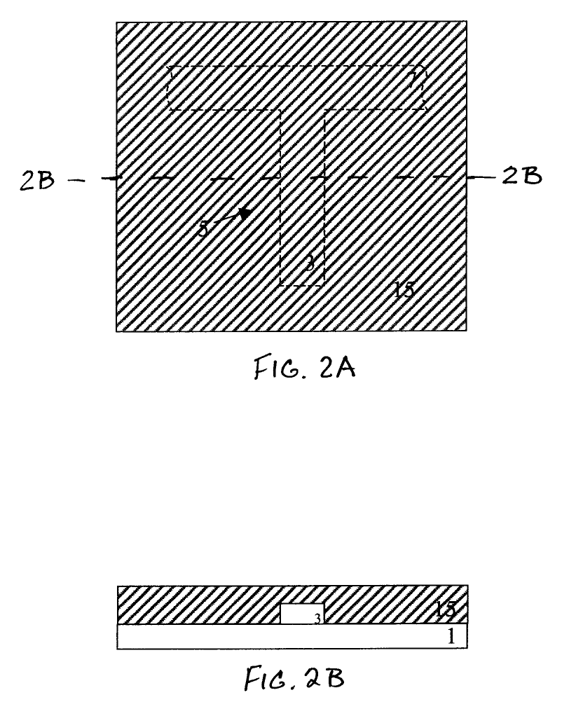

FIGS. 2A and 2B, in which FIG. 2B is a cross-section of the structure of FIG. 2A taken along the line 2B-2B of FIG. 2A illustrates a subsequent Step (b) of the present embodiment, directed to formation of a gate dielectric layer 15. A gate dielectric material is applied over the previous structure comprising substrate or support 1 and gate-bus structure 5, to form an unpatterned dielectric layer 15, best shown in cross-section in FIG. 2B.

The dielectric material can, for example, be plasma enhanced chemical vapor deposition of silicon nitride. Atmospheric chemical vapor deposition processes as disclosed in U.S. Ser. No. ______ and U.S. Ser. No. ______ (Dockets 93157 and 91866), hereby incorporated by reference in their entirety, may be used to deposit an inorganic oxide such as aluminum oxide. Other materials may be used, which can be applied by various means known to the skilled artisan.

The gate dielectric is provided in contact with the gate electrode. This gate dielectric electrically insulates the gate electrode from the balance of the TFT device. Thus, the gate dielectric comprises an electrically insulating material. The gate dielectric should have a suitable dielectric constant that can vary widely depending on the particular device and circumstance of use. For example, a dielectric constant from about 2 to 100 or even higher is known for a gate dielectric. Useful materials for the gate dielectric may comprise, for example, a transparent inorganic electrically insulating material. The gate dielectric may comprise a transparent polymeric material, such as polyvinylidenedifluoride (PVDF), cyanocelluloses, polyimides, etc. The gate dielectric may comprise a plurality of layers of different materials having different dielectric constants.

Specific examples of materials useful for the gate dielectric include strontiates, tantalates, titanates, zirconates, aluminum oxides, hafnium oxides, silicon oxides, tantalum oxides, titanium oxides, silicon nitrides, barium titanate, barium strontium titanate, barium zirconate titanate, zinc selenide, and zinc sulfide. In addition, alloys, combinations, and multilayers of these examples can be used for the gate dielectric. Of these materials, aluminum oxides, hafnium oxides, silicon oxides, and zinc selenide are preferred. In addition, polymeric materials such as polyimides, polyvinyl alcohol, poly(4-vinylphenol), polyimide, and poly(vinylidene fluoride), polystyrene and substituted derivatives thereof, poly(vinyl naphthalene) and substituted derivatives, and poly(methyl methacrylate) and other insulators having a suitable dielectric constant.

The gate dielectric can be provided in the TFT as a separate layer, or formed on the gate such as by oxidizing the gate material to form the gate dielectric. The dielectric layer may comprise two or more layers having different dielectric constants. Such insulators are discussed in U.S. Pat. No. 5,981,970 hereby incorporated by reference and copending U.S. patent application Ser. No. 11/088,645, hereby incorporated by reference. Gate insulator materials typically exhibit a band-gap of greater than about 5 eV.

The thickness of the gate insulator layer may vary, and according to particular examples it can range from about 10 to about 300 nm. The gate dielectric layer may be introduced into the structure by techniques such as chemical vapor deposition, sputtering, atomic layer deposition, or evaporation, solution.

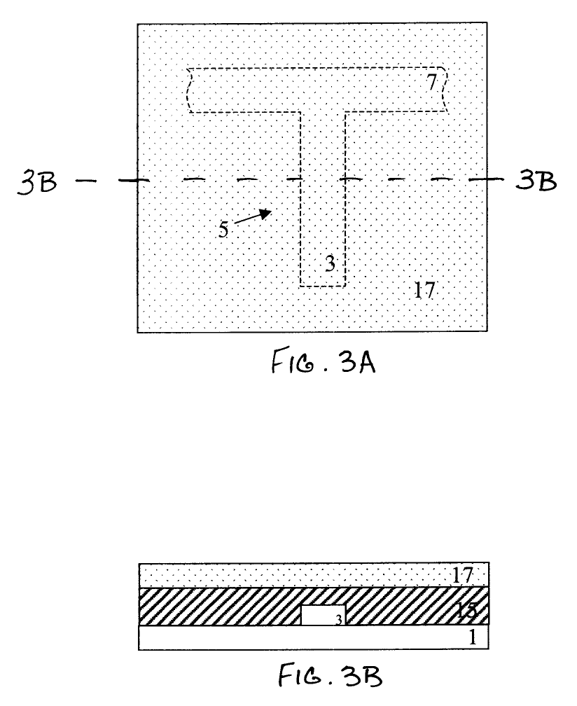

Referring now to FIG. 3A and FIG. 3B, in which FIG. 3B is a cross-section of the structure of FIG. 3A taken along the line 3B-3B of FIG. 3A, there is illustrated a subsequent Step (c) of the present embodiment, directed to formation of a semiconductor film. A zinc-oxide-based semi-conducting material is applied, for example, by inkjet printing, spin coating, chemical vapor deposition, atomic layer deposition, or the like, thereby forming the semiconductor film 17 over the gate dielectric layer 15 and gate-bus structure 5. Various embodiments for coating the zinc-oxide based semiconductor film are described in more detail below.

In many cases, a continuous film of semiconductor materials that stretches from a pixel to its neighbors can lead to a leakage of electrical current, causing poor pixel performance. Therefore, in the case of a plurality of thin film transistors comprising a plurality of semiconductor thin film elements each over a gate structure, which gate structure is connected via a bus line to other gate structures, wherein the passivation structure of a photoresist material over the thin film element in each transistor is in a shape that is vertically aligned with the shape of a plurality of gate structures and the bus line connecting them, the bus line is preferably not continuous between pixels at the time of passivation patterning. Alternately, various methods to pattern the layer of photoresist material can be used, as described below.

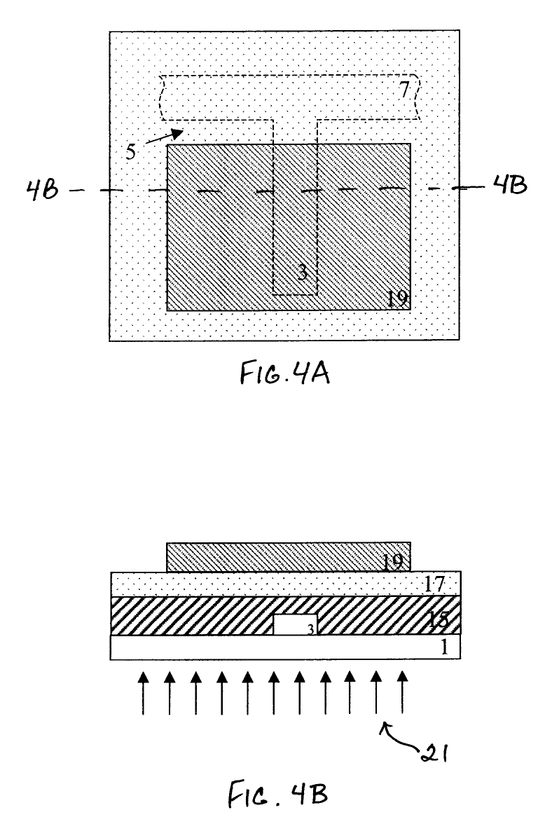

Referring now to the embodiment of FIG. 4A and FIG. 4B, in which FIG. 4B is a cross-section of the structure of FIG. 4A taken along the line 4B-4B of FIG. 4A, there is illustrated a subsequent Step (d) of the present embodiment, directed to formation of a partially patterned photopatternable photoresist layer 19, best shown in cross-section in FIG. 4B. This photopatternable photoresist layer 19 is made from unexposed positive-working photoresist material which is formed over the semiconductor thin film in regions not over the bus line.

This pattern of unexposed positive-working photoresist material can be formed by various methods. For example, the positive-working photoresist material can be selectively applied over the semiconductor film in regions not containing the bus line using an additive print process such as inkjet printing, gravure printing, or other known printing methods.

Alternatively, the positive-working photoresist material may be uniformly applied to the substrate and the regions overlaying the bus structure may be selectively exposed from the top side using a relatively low resolution mask (not shown). The resulting structure from this procedure forms the same pattern of unexposed photoresist as shown in FIGS. 4A and 4B, but in a continuous layer with exposed photoresist.

The photopatternable photoresist layer 19 in FIGS. 4A and 4B is then exposed with light rays 21 through the transparent substrate 1 with a light source (not shown), optionally through a relatively low resolution mask as further described below, wherein the light source is blocked by the gate-bus structure 5 or, in the absence of the bus line, gate structure 3.

The exact size and shape of the photopatternable photoresist layer 19 may vary, the key features being that unexposed photoresist completely covers the channel region of the TFT, and does not extend in a continuous section from the channel region of one TFT to the channel region of any adjacent TFT's. Additionally, for embodiments 2 and 3 discussed later, the unexposed photoresist layer covers the regions where fluid containment barriers are to be located.

The positive-working photoresist material used to make the passivation structure, in one preferred embodiment, is at least 0.05 microns thick, more preferably at least about 0.1 microns to 5 microns thick.

A variety of positive-working photoresist systems can be employed. Various positive-working resist materials and formulations are described in “Photoreactive Polymers: The Science and Technology of Resists” by A. Reiser, Wiley-Interscience, John Wiley & Sons, 1989, pp. 178-223. Particularly useful positive-working photoresists contain a phenol-formaldehyde polycondensate known as novolak, generally synthesized using cresol rather than phenol, with the polycondensation reaction halted before the polymer becomes crosslinked.

Being phenols, these polymers are soluble in aqueous base, although the rate of dissolution is quite slow. However, in the presence of suitable additives, the dissolution process can be greatly enhanced. The additives can be produced photochemically, leading to a useful photoresist system. In fact, novolak-based resists have been the “workhorse” photoresists of the modern microelectronic revolution.

In a preferred embodiment, the photoresist consists of novolak-based polymer, with a small amount of diazonaphthaquinone dissolved in it. When irradiated by actinic radiation in the present method, the diazonaphthaquinone undergoes the photochemical Wolf rearrangement, which eventually produces a carboxylic acid, as represented below:

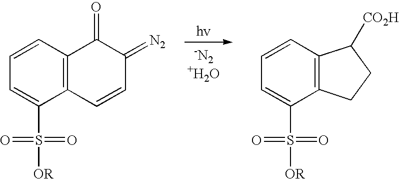

The carboxylic acid (produced by irradiation) is even more soluble in base then the novolak resin itself. Its presence increases the rate of dissolution of the coating by orders of magnitude. Therefore the unirradiated regions are effectively insoluble, leading to a positive photoresist.

It is required that the sensitivity distribution of the positive-working photoresist layer overlaps with the transmittance spectrum of the support material, that is, the positive-working photoresist layer must be capable of responding to a pre-selected spectrum of actinic radiation which is transmitted by the support material and blocked by the non-transmissive gate structure. Typically, novolak-based photoresists sensitized with diazo photosensitive compositions such as are described above are intended to be exposed with a UV light source. As a result, these photoresists are most sensitive to wavelengths between about 350 nm to 410 nm. However, manyplastic substrates are non-transmissive or poorly transmissive at these wavelengths. By way of example, polyimide materials, such as KAPTON, is a deep yellow, and PEN is transmits wavelengths above about 400 nm.

Consequently, in a preferred embodiment, particularly when the invention is practiced on plastic supports, the positive-working resist layer should be capable of responding to wavelengths greater than 400 nm (and below 1000 nm). By way of example, U.S. Pat. No. 4,708,925 (hereby incorporated by reference) describes a positive-working photosolulizable composition containing novolak phenolic resins, an onium salt, and a dye sensitizer. In this system, there is an interaction between alkali-soluble phenolic resins and onium salts which results in an alkali solvent resistance when it is cast into a film. Photolytic decomposition of the onium salt restores solubility to the resin. Unlike the quinine diazides which can only be poorly sensitized, if at all, onium salts can be readily sensitized to a wide range of the electromagnetic spectrum from UV to infrared (280 to 1100 nm).

Examples of compounds which are known to sensitize onium salts are those in the following classes: diphenylmethane including substituted diphenylmethane, xanthene, acridine, methine and polymethine (including oxonol, cyanine, and merocyanine) dye, thiazole, thiazine, azine, aminoketone, porphyrin, colored aromatic polycyclic hydrocarbon, p-substituted aminostyryl compound, aminotriazyl methane, polyarylene, polyarylpolyene, 2,5-diphenylisobenzofuran, 2,5-diarylcyclopentadiene, diarylfuran, diarylthiofuran, diarylpyrrole, polyaryl-phenylene, coumarin and polyaryl-2-pyrazoline. The addition of a sensitizer to the system renders it sensitive to any radiation falling within the absorption spectrum of the said sensitizer. Other positive-working systems are known to those skilled in the art.

In an alternative embodiment of the present invention, after coating the photoresist, the photoresist material may be treated with fluorinated silane or other fluorinated coating to make the top hydrophobic, before developing and washing. This treatment affects the surface energy such that the subsequently deposited source and drain “inks” (for example, silver nanoparticle compositions) dewet from the photoresist. Thus, a hydrophobic surface can be optionally used to improve the desired positioning or alignment of the source and drain electrodes. Alternatively still, a fluorinated photoresist may be used.

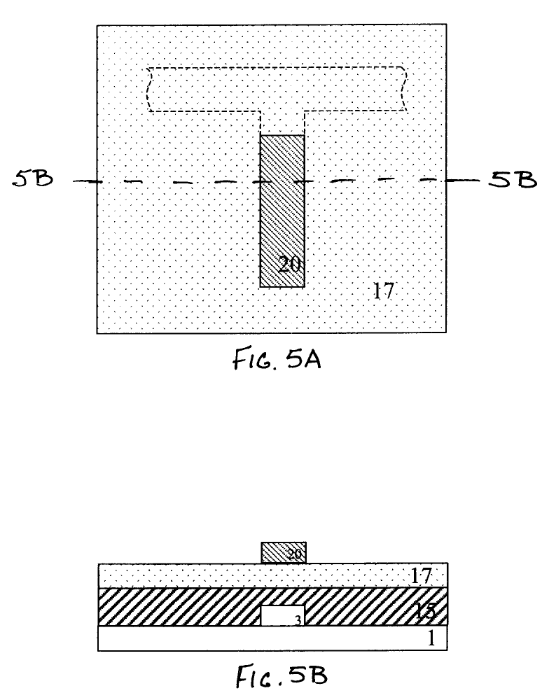

Referring now to FIG. 5A and FIG. 5B, in which FIG. 5B is a cross-section of the structure of FIG. 5A taken along the line 5B-5B of FIG. 5A, there is illustrated a subsequent Step (e) of the present embodiment, directed to formation of a passivation layer 20. When the photopatternable photoresist layer 19 was exposed with light rays 21 through the transparent substrate 1 and the light source blocked by the gate-bus structure 5, but not blocked by the semiconductor film 17 or other substantially transparent layers, the photoresist layer 19 was exposed everywhere around the area formed by the gate-bus structure. Subsequently, the photoexposed photoresist layer 19 was developed and washed to form the passivation layer 20 in a pattern that mimics the shape of the gate-bus structure 5. The elongated first and second boundaries formed by the photopatterned passivation layer is aligned with the elongated boundaries or sides 9 and 11 of the gate electrode 3. These elongated sides form a fluid barrier to subsequently applied fluid used to form the source and drain electrodes. These fluid barriers provided by the passivation layer 20 are aligned with the underlying gate electrode.

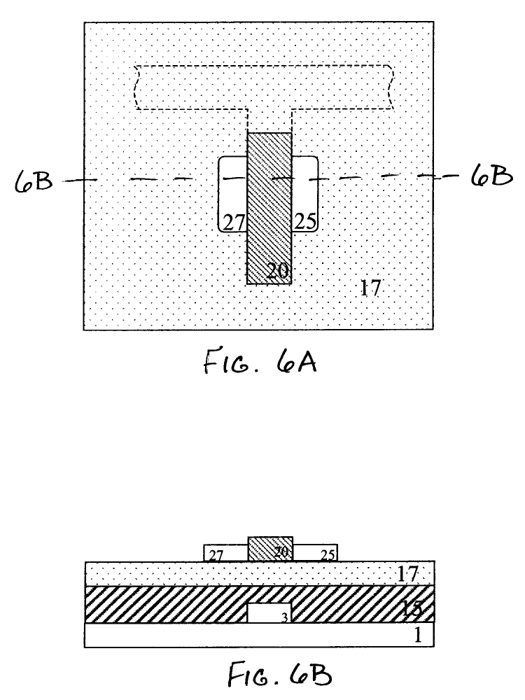

Referring now to FIG. 6A and FIG. 6B, in which FIG. 6B is a cross-section of the structure of FIG. 6A taken along the line 6B-6B of FIG. 6A, there is illustrated a subsequent Step (f) of the present embodiment, directed to formation of a source 25 and drain 27, defining an area, the elongated boundaries of which passivation structure is aligned with and over the gate electrode 5. For example, a coating composition comprising a metal, a conducting polymer such as PEDOT:PSS, or other conductive material can be deposited and patterned to form a source and drain on either side of the aligned passivation layer 20. In the case of nanoparticles or other conductor precursor, an annealing step may be necessary to form the conductive contacts.

Source/drain terminals refer to the terminals of a TFT, between which conduction occurs under the influence of an electric field. Designers often designate a particular source/drain terminal to be a “source” or a “drain” on the basis of the voltage to be applied to that terminal when the TFT is operated in a circuit.

The source electrode and drain electrode are separated from the gate electrode by the gate dielectric and the zinc-oxide-based semiconductor layer. The source and drain electrodes can be any useful conductive material. Useful materials include most of those materials described above for the gate electrode, for example, aluminum, barium, calcium, chromium, gold, silver, nickel, palladium, platinum, titanium, copper, tungsten, polyaniline, PEDOT:PSS, other conducting polymers, alloys thereof, combinations thereof, and multilayers thereof. Particularly useful materials include a variety of printable conductor materials known in the art, such as carbon ink, silver-epoxy, or sinterable metal nanoparticle suspensions. Other illustrative materials include transparent, n-type conductors such as indium-tin oxide (ITO), ZnO, SnO₂, or In₂O₃. Preferred electrodes are silver, gold, ITO, or aluminum.

The source electrode and drain electrode can be provided by any useful means such as chemical or physical vapor deposition (e.g., thermal evaporation, sputtering), evaporation, chemical vapor deposition, atomic layer deposition, ink jet printing, vapor jet printing, or solution deposition. The patterning of these electrodes can be accomplished by known methods such as printing, microcontact printing, and pattern coating. The source and drain terminals may be fabricated such that they are geometrically symmetrical or non-symmetrical.

Electrical contact to the gate electrode, source, drain and substrate may be provided in any manner. For example, metal lines, traces, wires, interconnects, conductors, signal paths and signaling mediums may be used for providing the desired electrical connections. The related terms listed above, are generally interchangeable, and appear in order from specific to general. Metal lines, generally aluminum (Al), copper (Cu) or an alloy of Al and Cu, are typical conductors that provide signal paths for coupling or interconnecting, electrical circuitry. Conductors other than metal may also be utilized.

In cases where another layer covers the electrical contact of interest, connection to the electrical contact can be made by creating a “via” that penetrates to the contact. Such vias can be made by convenient patterning operations such as lithography, etching, or laser based processes.

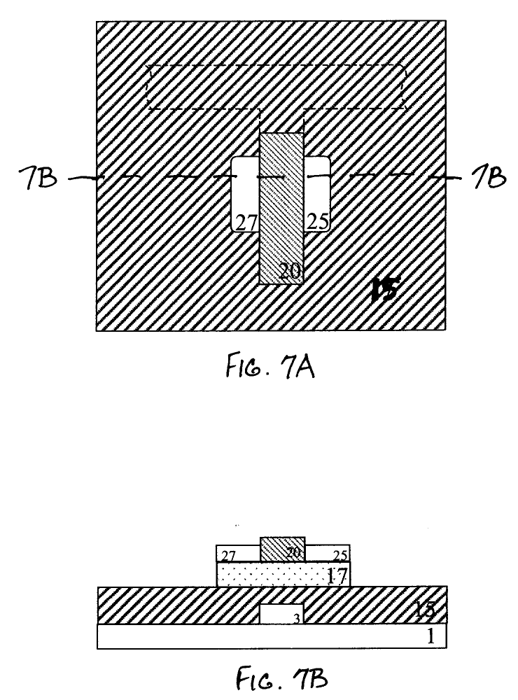

Referring now to FIG. 7A and FIG. 7B in which FIG. 7B is a cross-section of the structure of FIG. 7A taken along the line 7B-7B of FIG. 7A, there is illustrated a subsequent Step (g) of the present embodiment, in which the semiconductor continuous layer 17 is patterned by employing a fluid composition, for example an acid-etch solution, capable of removing unprotected zinc-oxide-based material. Since the source and drain material and the passivation layer 20 are immune from the acid-etch solution or the like, the outer boundaries of the semiconductor film is aligned with the source and drain boundaries.

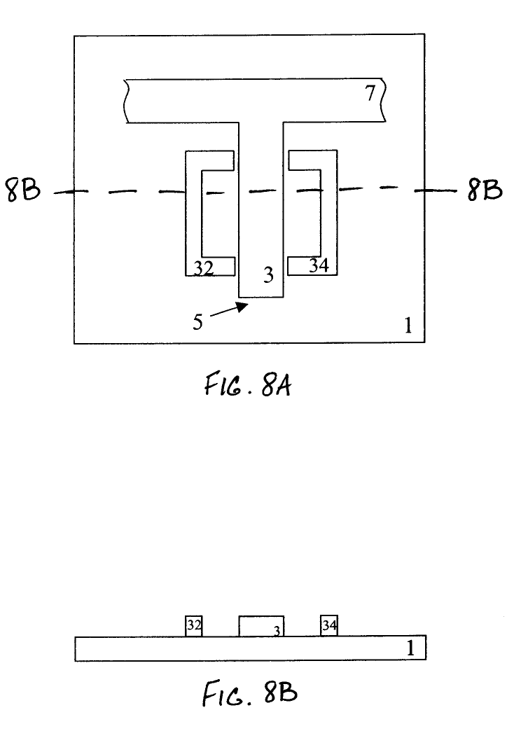

Another (second) embodiment of a process according to the present invention will now be described, referring to FIG. 8A and FIG. 8B, in which FIG. 8B is a cross-section of the structure of FIG. 8A taken along the line 8B-8B of FIG. 8A. In Step (a) of this second embodiment, the gate material is deposited not only to form a gate-bus structure 5 (or gate electrode 3 alone in the absence of the bus line 7), but also forms internal side photomask elements 32 and 34 for later forming outer containment elements 22 and 23 that serve as outer barriers to the fluid forming the source and drain. Subsequent Steps (b), (c), and (d) can be carried out analogously as in the first embodiment illustrated in FIGS. 2A, 2B through FIGS. 4A, 4B (except with the continued presence of the internal side photomask elements).

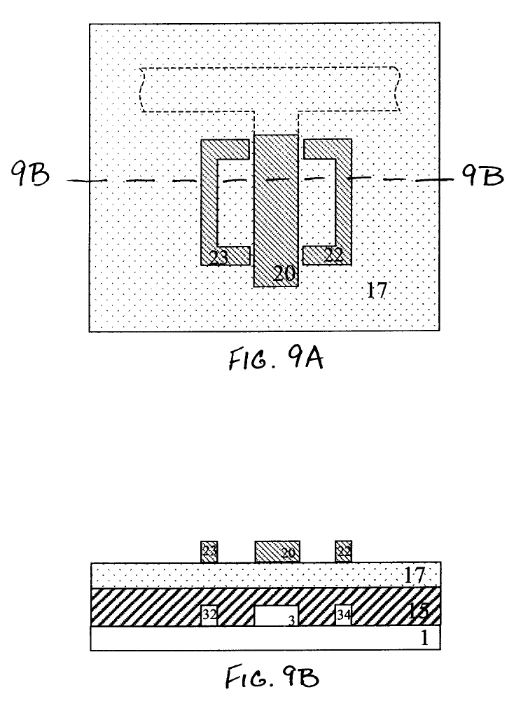

Step (e) of the second embodiment is illustrated in FIG. 9A and FIG. 9B, in which FIG. 9B is a cross-section of the structure of FIG. 9A taken along the line 9B-9B of FIG. 9A. In Step (e) of this second embodiment, in addition to the photopatterned passivation layer 20, the developed photoresist material further comprises isolated outer containment elements 22 and 23. In some cases, the outer containment elements 22 and 23 may bridge the small gap with the passivation layer 20, because of optical and/or development blurring, which would actually be desirable to completely surround the subsequent source and drain materials. The containment elements 22 and 23 can be in other shapes, besides the bracket shape of FIG. 9A. Other shapes include a straight elongated bar or an “L” shape in which the bottom of the L faces the distal end of the passivation layer 20. The shape and size of the two containment elements 22 and 23 may be different, or a containment element may only be present on one side of the passivation layer 20, with respect to only one of either the source 25 or the drain electrode 27. For example, in practice, the source and the drain may differ in size and shape and hence correspondingly different shapes and sizes for the containment elements 22 and 23 may be appropriate or desirable. For example, since the drain may be in the shape of a pixel or connected to a pad that lights up the pixel, the shape and outer containment element may be designed accordingly. The source and or drain electrodes may also adopt a shape that allows it to perform multiple functions. For example, a particular source or drain electrode may have a region separated from another conductor by a dielectric to create a pixel capacitor. Furthermore, although most pixel designs utilize source and drain electrodes which are spaced apart by a linear channel, other shapes are possible including ones that introduce curvature.

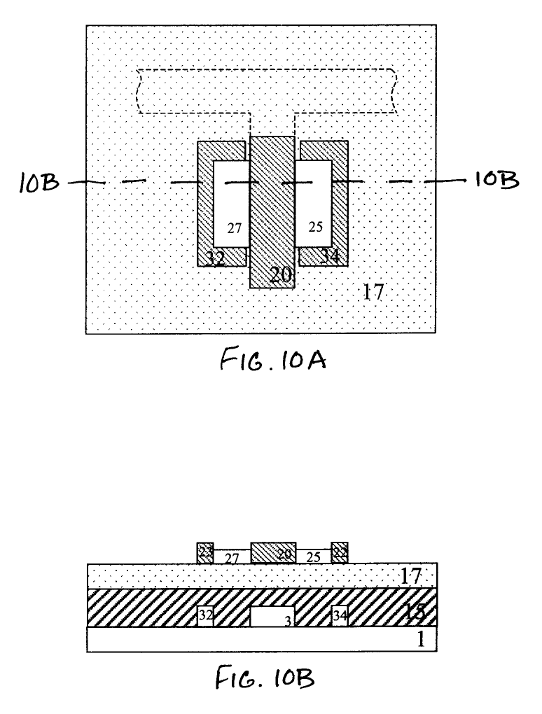

Step (f) of the second embodiment is illustrated in FIG. 10A and FIG. 10B, in which FIG. 10B is a cross-section of the structure of FIG. 10A taken along the line 10B-10B of FIG. 10A. In Step (f) of this second embodiment, in comparison to Step (f) of the first embodiment shown in FIGS. 6A, 6B, the source and drain is shown surrounded, at least partially, on all four sides, by the boundaries formed by passivation layer 20 and additionally outer containment elements 22 and 23.

The second embodiment differs from the first embodiment in the addition of opposed side barriers or outer containment elements for the source and drain, opposed to the aligned passivation structure, which barriers were also formed from the coated photoresist layer.

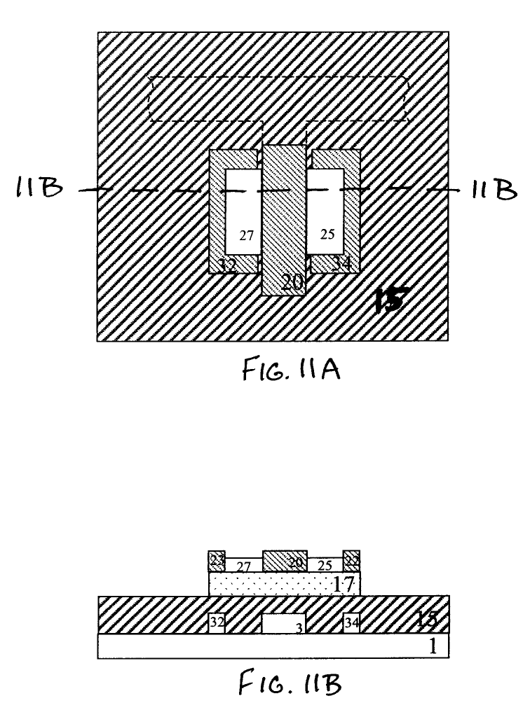

Step (g) of the second embodiment is illustrated in FIG. 11A and FIG. 11B, in which FIG. 11B is a cross-section of the structure of FIG. 11A taken along the line 11B-11B of FIG. 11A. In Step (g) of this second embodiment, as in the first embodiment, the continuous semiconductor film 17 is patterned by employing a fluid composition, for example an acid-etch solution, capable of removing unprotected zinc-oxide-based material. Since the source and drain material and the developed photoresist layer (both the passivation layer 20 and the containment elements 22 and 23) is immune from the acid-etch solution or the like, the outer boundaries of the semiconductor film 17 is aligned with the source and drain boundaries only where not surrounded by the containment elements 22 and 23. Otherwise the outer boundaries of the semiconductor film 17 are aligned with the containment elements 22 and 23.

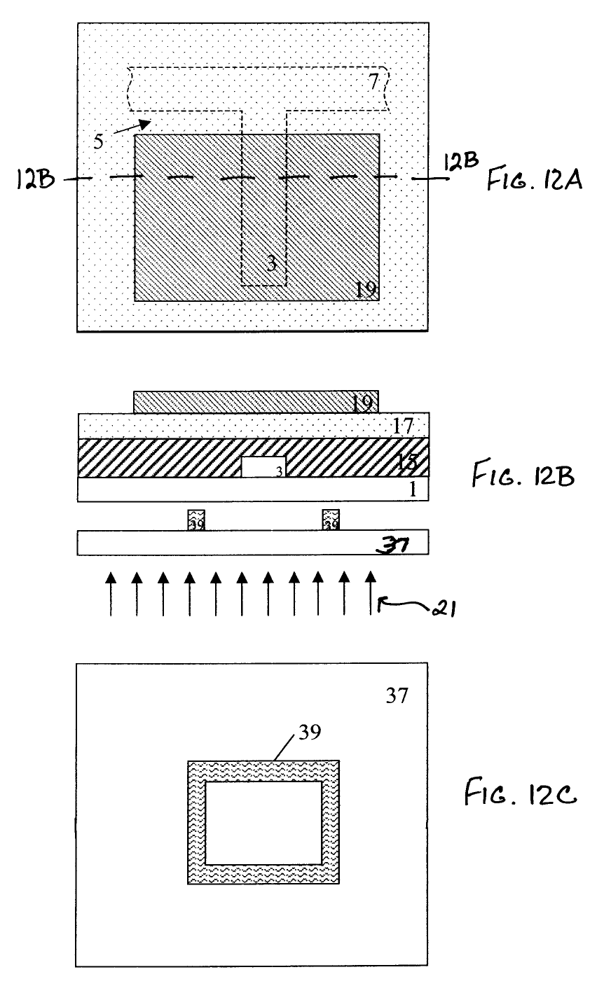

Yet a third embodiment shows another method of forming opposed side barriers or outer containment elements. The gate material, the gate dielectric, and the semiconductor are formed as in the first embodiment, corresponding respectively to Steps (a) to (c). However, Steps (d) to (f) differ from the first embodiment, as will now be described. Referring to FIG. 12A and FIG. 12B, in which FIG. 12B is a cross-section of the structure of FIG. 12A taken along the line 12B-12B of FIG. 12A, and FIG. 12C shows a plan view of a relatively low resolution photomask 37 shown in side view in FIG. 12B. The term “relatively low resolution” is herein defined as the precision associated with the positioning of the photomask 37 and its aligned corresponding structure made from the photoresist material can be lower than the precision used in aligning the elongated sides of the semiconductor channel, horizontally relative to the elongated sides of the gate structure.

In Step (d) of the third embodiment (in comparison to the method of FIGS. 4A, 4B of the first embodiment), the partially patterned photoresist layer 19 is exposed from the substrate or support side through the low resolution photomask 37 having masked portion 39 in the form of (in this particular embodiment) a frame. The photomask 37 can be in contact with the support. Other shapes for the masked portion 39 of the photomask 37 may be employed, for example, parallel bars, as will be appreciated by the skilled artisan in view of the above description of alternate shapes and sizes for the outer containment elements that are produced using the masked portion 39.

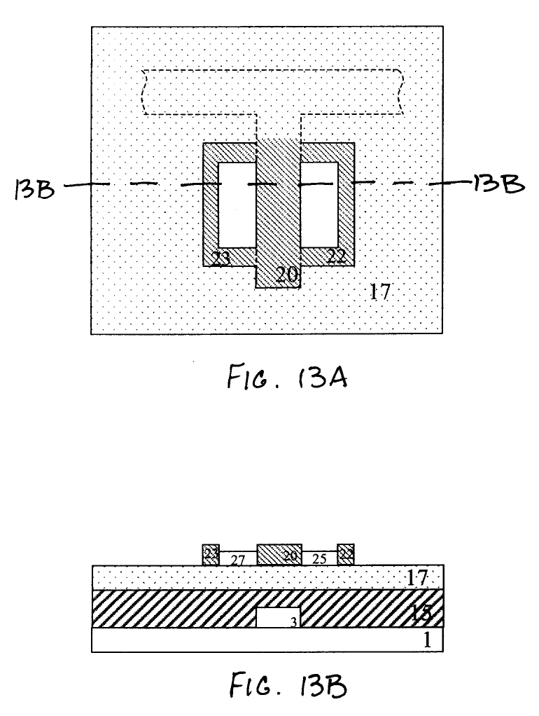

Based on the frame shape of FIG. 12C, however, a photopatterned photoresist layer 20 is produced as shown in FIG. 13A, wherein both Step (e) and (t) are illustrated. The photopatterned photoresist layer 19 forms not only a central portion or passivation layer 20, but also outer containment elements 22 and 23. The skilled artisan will readily appreciate that, were a slightly different photomask used in Step (e), then a photopatterned resembling that shown in FIGS. 9A, 9B could have been obtained. In this embodiment of FIGS. 13A, 13B, however, the photopattern overall forms continuous side barriers to an applied fluid for the source and drain, without gaps in the barriers. An aligned containment element, however, has at least one, preferably three sides, opposed to the side formed by the passivation structure 20 covering the semiconductor element. Again, as with the second embodiment, the fluid containment elements 22 and 23 can be in other shapes, including a straight bar or an L shape. In Step (f) of this third embodiment, as illustrated in FIGS. 13A, 13B, in comparison to Step (f) of the first embodiment shown in FIGS. 6A, 6B and similar to Step (f) of FIGS. 10A, 10B of the second embodiment, the source and drain is shown surrounded on more than one side, in this case on all four sides, by the photopatterned passivation layer 20 in combination with the outer containment elements 22 and 23.

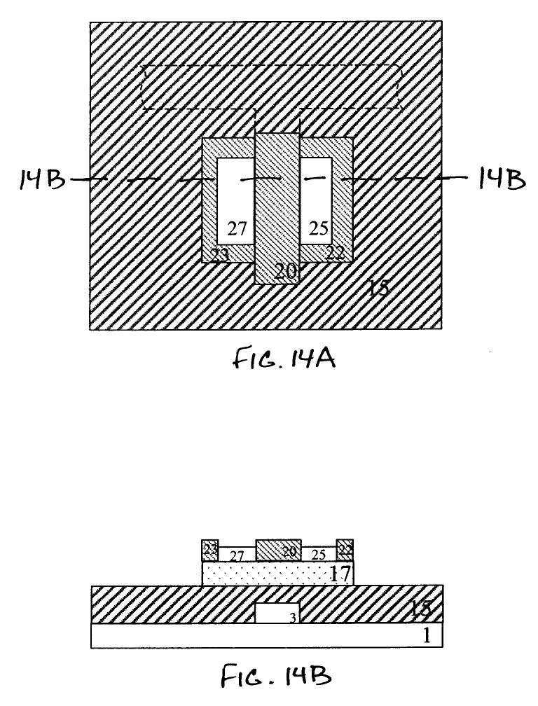

Finally, for this embodiment, the third embodiment, Step (g) is illustrated in FIG. 14A and FIG. 14B, in which FIG. 14B is a cross-section of the structure of FIG. 14A taken along the line 14B-14B of FIG. 14A. In Step (g) of this second embodiment, as in the first and second embodiment, the continuous semiconductor film 17 is patterned by employing a fluid composition, for example an acid-etch solution, capable of removing unprotected zinc-oxide-based material. Since the source and drain material and the developed photoresist layer (both the passivation layer 20 and the containment elements 22 and 23) are immune from the acid-etch solution or the like, the outer boundaries of the semiconductor film 17 is aligned with the source and drain boundaries only where not surrounded by the containment elements 22 and 23. Otherwise, outer boundaries of the semiconductor film is aligned with the outer containment elements 22 and 23.

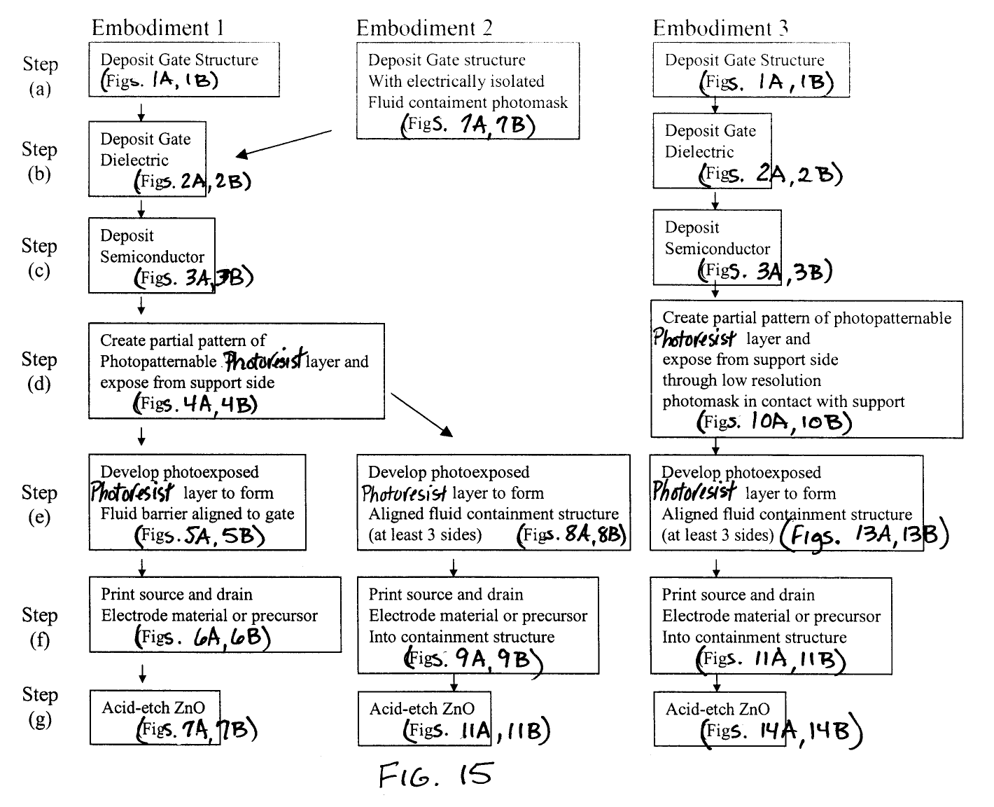

A process flow diagram which summarizes the first, second, and third embodiments illustrating the present invention is shown in FIG. 15. Each of the boxes correspond to one of the Steps (a) to (g) of the process and are self-explanatory. Thus, in the first embodiment, the Steps (a) to (g) sequentially comprise depositing a gate metal, depositing a gate dielectric, coating a semiconductor material, coating a photopatternable photoresist layer and exposing it from the support side, developing the photoexposed photoresist material to form a passivation layer aligned to the gate structure, and printing a source and drain electrode material or precursor thereof. The second embodiment most notably differs in Steps (a) and Steps (e) to (g), wherein Step (a) additionally comprises depositing not only gate metal but also the pattern for an electrically isolated fluid containment element, which acts as a photomask in subsequent Step (d). Subsequently, the photoexposed photoresist layer is developed to form an aligned fluid containment element. The source or drain is then formed bounded on one at least one side within this containment element, of which another side of the source or drain is bounded by the passivation layer that has been aligned with the gate electrode. In the third embodiment, the photopatternable photoresist layer is exposed from the support side through a relatively low-resolution photomask which can be in contact with the support. The developed photoexposed photoresist layer then forms an aligned fluid containment element having sides aligned with the photomask. Finally, the source and drain, or a precursor thereof, is printed into the overall containment structure formed by the passivation layer and the outer containment element or elements.

The entire process of making the thin film transistor or electronic device of the present invention, or at least the production of the thin film semiconductor, can be carried out below a maximum support temperature of about 200° C., more preferably below 150° C., most preferably below about 140° C., and even more preferably below about 100° C., or even at temperatures around room temperature (about 25° C. to 70° C.). The temperature selection generally depends on the support and processing parameters known in the art, once one is armed with the knowledge of the present invention contained herein. These temperatures are well below traditional integrated circuit and semiconductor processing temperatures, which enables the use of any of a variety of relatively inexpensive supports, such as flexible polymeric supports. Thus, the invention enables production of relatively inexpensive circuits containing thin film transistors with significantly improved performance. One embodiment of the present invention is directed to a process for fabricating a thin film transistor, preferably by deposition of the semiconductor thin film onto a substrate, preferably wherein the substrate temperature is at a temperature of no more than 200° C. during the deposition.

The present method of making the zinc-oxide-based semiconductor thin film, for use in thin film transistors, employs a zinc-oxide-based material that can contain minor amounts of other metals capable of forming semiconducting oxides such as indium, tin, or cadmium, and combinations thereof. For example, Chiang, H. Q. et al., “High mobility transparent thin-film transistors with amorphous zinc tin oxide channel layer,” Applied Physics Letters 86, 013503 (2005) discloses zinc tin oxide materials.

Minor amounts of optional acceptor or donor dopants, preferably less than 10 weight percent, can also be included in the nanoparticles before or after deposition. Accordingly, the term “zinc-oxide-based” refers to a composition comprising zinc oxide as the predominant metal oxide, preferably greater than 50 percent by weight, more preferably at least 80 percent by weight, but allowing additives or mixtures with minor amounts of other metal oxides, which semiconductor compositions are known to the skilled artisan.

Although undoped zinc-oxide-based nanoparticles can be employed in the present invention, the resistivity of the ZnO may be enhanced by substitutional doping with an acceptor dopant such as, for example, N, B, Cu, Li, Na, K, Rb, P, As, and mixtures thereof. Alternatively, p-type zinc-oxide films can be achieved, by the use of various p-type dopants and doping techniques. For example, U.S. Pat. No. 6,610,141 B2 to White et al. discloses zinc-oxide films containing a p-type dopant, for use in LEDs (light emitting devices), LDs (laser diodes), photodetectors, solar cells or other electrical devices where both n-type and p-type materials may be required for one or more multiple p-n junctions. White et al. employ diffusion of arsenic from a GaAs substrate to produce an arsenic-doped zinc-oxide-based film. U.S. Pat. No. 6,727,522 B1 also describes various dopants for p-type zinc-oxide-based semiconductor films, in addition to n-type dopants. Electrical devices in which zinc oxide is used as the n-type semiconductor and a different metal oxide, such as copper oxide or sodium cobalt oxide, is used as a p-type metal oxide are also known, as for example, described in EP 1324398 A2. Thus, the present invention can be used to make one or more semiconductor thin films in the same electrical device having a p-n junction, either by variously doped zinc-oxide-based semiconductor thin films made by the present method or by a zinc-oxide-based semiconductor thin film in combination with one or more other zinc-oxide semiconductor thin films known in the art. For example, an electrical device made according to the present invention can include a p-n junction formed using a zinc-oxide-based thin film semiconductor made by the present method in combination with a thin film semiconductor of complementary carrier type as known in the art.

The thickness of the channel layer in the semiconductor material may vary, and according to particular examples it can range from about 5 nm to about 150 nm, preferably 10 to 100 nm. The length and width of the channel is determined by the pixel size and the design rules of the system under construction. Typically, the channel width may vary from 10 to 1000 μm. The channel length may vary, and according to particular examples it can range from about 1 to about 100 μm.

The semiconductor films made according to the present method exhibit a field effect electron mobility that is greater than 0.01 cm²/Vs, preferably at least 0.1 cm²/Vs, more preferably greater than 0.2 cm²/Vs. In addition, n-channel semiconductor films made according to the present invention are preferably capable of providing on/off ratios of at least 10⁴, advantageously at least 10⁵. The on/off ratio is measured as the maximum/minimum of the drain current as the gate voltage is swept from one value to another that are representative of relevant voltages which might be used on the gate line of a display. A typical set of values would be −10V to 40V with the drain voltage maintained at 30V.

The thin film of zinc-oxide-based semiconductor can be formed by various low temperature processes, including chemical vapor deposition (CVD), atomic layer deposition (ALD), or the deposition of a colloidal solution of nanoparticles, etc. Still other coating techniques include spin coating, extrusion coating, hopper coating, dip coating, or spray coating. In a commercial scale process, the semiconductor film can be coated on a web substrate that is later divided into individual semiconductor films.

Alternately, an array of semiconductor films can be coated on a moving web. Embodiments of some of these coating techniques will now be described in greater detail.

In the case of thin film semiconductor formation using nanoparticles, a particularly preferred embodiment comprises depositing a colloidal solution of zinc-oxide-containing nanoparticles on a substrate, at a substrate temperature of 200° C. or less. Charge stabilized sols are stabilized by repulsion between particles based on like surface charges. See, for example, C. Jeffrey Brinker and George W. Scherer, The Physics and Chemistry of Sol-Gel Processing, Academic Press (New York 1989).

In one embodiment, the nanoparticles can be the reaction product of reactants comprising an organozinc precursor compound and a basic ionic compound that form a zinc-oxide-containing material and have an average primary particle size in the range of 10 to 150 nm, preferably 20 to 100 nm. It has been found that the performance of the film may be enhanced by carefully controlling the composition of the colloidal solution. Preferably the nanoparticles are colloidally stabilized in a colloidal solution in which the level of inorganic ions in the colloidal solution is below 1 mM and the level of organic compounds, or salts thereof, is below 5 mM. Preferably, the colloidal solution of nanoparticles is applied to the substrate at a level of 0.02 to 1 g/m² of nanoparticles, by dry-weight.

The colloidal solution of nanoparticles can be applied by various methods, including conventional coating techniques for liquids. In one embodiment, the colloidal solution of nanoparticles is applied using an inkjet printer. The inkjet printer can be a continuous or drop-on-demand inkjet printer. In a conventional inkjet printer, the method of inkjet printing a semiconductor film on a substrate element typically comprises: (a) providing an inkjet printer that is responsive to digital data signals; (b) loading a first printhead with the colloidal solution of nanoparticles; (c) printing on the substrate using the colloidal solution in response to the digital data signals; and (d) annealing the printed substrate.

The zinc-oxide-based nanoparticles can be formed from the reaction of an organometallic precursor such as zinc acetate that is hydrolyzed with a base such as potassium hydroxide. Other organometallic precursor compounds can include, for example, zinc acetylacetonate, zinc formate, zinc hydroxide, zinc chloride, zinc nitrate, their hydrates, and the like. Preferably, the organometallic precursor compound is a zinc salt of a carboxylic acid, or a hydrate thereof, more preferably zinc acetate or a hydrate thereof. Optional doping materials can include, for example, aluminum nitrate, aluminum acetate, aluminum chloride, aluminum sulfate, aluminum formate, gallium nitrate, gallium acetate, gallium chloride, gallium formate, indium nitrate, indium acetate, indium chloride, indium sulfate, indium formate, boron nitrate, boron acetate, boron chloride, boron sulfate, boron formate, and their hydrates.

After particle formation, the level of ions can be reduced, by washing, to obtain a stable dispersion. Too many ions in the solution can cause a screening of the particles from each other so that the particles approach too closely leading to aggregation and thus poor dispersion. Preferably, repeated washings allow the inorganic ion level to reach the desired concentration of below 1 mM. The level of organic compounds, or salts thereof, is maintained below a level of 5 mM.

In one embodiment of the invention, the zinc-oxide-based semiconductor thin film comprises supplemental material, or a subsequent layer, formed from an overcoat solution. In particular, the semiconductor properties of the thin film can be enhanced by further steps, after applying, to a substrate, the colloidal solution of zinc-oxide-based nanoparticles, drying the coating to form a porous layer of zinc-oxide-based nanoparticles, and optionally annealing the porous layer of zinc-oxide-based nanoparticles. The optional further steps comprise applying, over the porous layer of nanoparticles, an overcoat solution comprising a soluble zinc-oxide-precursor compound that converts to zinc oxide upon annealing, to form an intermediate composite film; drying the intermediate composite film; and annealing the dried intermediate composite film at a temperature of at least 50° C., suitably up to 300° C., to produce a semiconductor film comprising zinc-oxide-based nanoparticles supplemented by additional zinc oxide material formed by the conversion of the zinc-oxide-precursor compound during the annealing of the composite film.

Preferably, in this embodiment the colloidal solution of nanoparticles is applied to the substrate at a level of 0.02 to 1 g/m² of nanoparticles, by dry-weight, and the overcoat solution is preferably applied at a level of 2×10⁻⁴ to 0.01 moles/m² of precursor compound. In such a preferred embodiment, the molar ratio of nanoparticles to theoretically converted zinc-oxide precursor compound is approximately 0.02 to 60, based on moles of ZnO and precursor compound present.

According, in one embodiment of making a thin film comprising a zinc-oxide-based semiconductor using nanoparticles of the semiconductor material, the method comprises:

(a) applying, to a substrate, a seed coating comprising a colloidal solution of zinc-oxide-based nanoparticles having an average primary particle size of 5 to 200 nm;

(b) drying the seed coating to form a porous layer of zinc-oxide-based nanoparticles;

(c) optionally annealing the porous layer of zinc-oxide-based nanoparticles at a temperature higher than the temperature of step (a) or (b);

(d) applying, over the porous layer of nanoparticles, an overcoat solution comprising a soluble zinc-oxide-precursor compound that converts to zinc oxide upon annealing, to form an intermediate composite film;

(e) drying the intermediate composite film; and

(f) annealing the dried intermediate composite film at a temperature of at least 50° C. to produce a semiconductor film comprising zinc-oxide-based nanoparticles supplemented by additional zinc oxide material formed by the conversion of the zinc-oxide-precursor compound during the annealing of the composite film.

This particular type of process can be referred to as a bilayer semiconductor film.

In another coating technique, a thin film of zinc-oxide-based nanoparticles may be applied by spin coating and subsequently annealed for about 10 seconds to 10 minute, preferably 1 minute to about 5 minutes in certain instances, at a temperature of about 50 to 500° C.

In the case of forming the thin film semiconductor by chemical vapor deposition at low temperature, various methods of chemical vapor deposition (CVD) are well known in the art.

In one preferred embodiment, the semiconductor thin film layer in the present method is deposited by an atomic layer deposition (ALD) process as described below. Not only the semiconductor thin film layer can be deposition by ALD, since ALD (atomic layer deposition) is also suited for forming thin layers of metal oxides or metals in the components of electronic devices. General classes of functional materials that can be deposited with ALD include conductors, dielectrics or insulators, and semiconductors.

Advantageously, ALD steps are self-terminating and can deposit precisely one atomic layer when conducted up to or beyond self-termination exposure times. An atomic layer typically ranges from about 0.1 to about 0.5 molecular monolayers, with typical dimensions on the order of no more than a few Angstroms. In ALD, deposition of an atomic layer is the outcome of a chemical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the complete absence of the other precursor or precursors of the reaction. In practice in any process it is difficult to avoid some direct reaction of the different precursors leading to a small amount of chemical vapor deposition reaction. The goal of any process claiming to perform ALD is to obtain device performance and attributes commensurate with an ALD process while recognizing that a small amount of CVD reaction can be tolerated.

In ALD applications, typically two molecular precursors are introduced into the ALD reactor in separate stages. For example, a metal precursor molecule, MLx, comprises a metal element, M that is bonded to an atomic or molecular ligand, L. For example, M could be, but would not be restricted to, Al, W, Ta, Si, Zn, etc. The metal precursor reacts with the substrate, when the substrate surface is prepared to react directly with the molecular precursor. For example, the substrate surface typically is prepared to include hydrogen-containing ligands, AH or the like, that are reactive with the metal precursor. Sulfur (S), oxygen (O), and Nitrogen (N) are some typical A species. The gaseous precursor molecule effectively reacts with all of the ligands on the substrate surface, resulting in deposition of a single atomic layer of the metal:

substrate-AH+MLₓ→substrate-AMLₓ₋₁+HL (1)

where HL is a reaction by-product. During the reaction, the initial surface ligands, AH, are consumed, and the surface becomes covered with AMLₓ₋₁ ligands, which cannot further react with metal precursor MLₓ. Therefore, the reaction self-terminates when all of the initial AH ligands on the surface are replaced with AMLₓ₋₁ species. The reaction stage is typically followed by an inert-gas purge stage that eliminates the excess metal precursor and the HL by-product species from the chamber prior to the separate introduction of the other precursor.

A second molecular precursor then is used to restore the surface reactivity of the substrate towards the metal precursor. This is done, for example, by removing the L ligands and re-depositing AH ligands. In this case, the second precursor typically comprises the desired (usually nonmetallic) element A (i.e., O, N, S), and hydrogen (i.e., H₂O, NH₃, H₂S). The next reaction is as follows:

substrate-A-ML+AH_{Y}→substrate-A-M-AH+HL (2)

This converts the surface back to its AH-covered state. (Here, for the sake of simplicity, the chemical reactions are not balanced.) The desired additional element, A, is incorporated into the film and the undesired ligands, L, are eliminated as volatile by-products. Once again, the reaction consumes the reactive sites (this time, the L terminated sites) and self-terminates when the reactive sites on the substrate are entirely depleted. The second molecular precursor then is removed from the deposition chamber by flowing inert purge-gas in a second purge stage.

In summary, then, an ALD process requires alternating in sequence the flux of chemicals to the substrate. The representative ALD process, as discussed above, is a cycle having four different operational stages:

1. MLₓ reaction;

2. MLₓ purge;

3. AH_{y} reaction; and

4. AH_{y} purge, and then back to stage 1.

This repeated sequence of alternating surface reactions and precursor-removal that restores the substrate surface to its initial reactive state, with intervening purge operations, is a typical ALD deposition cycle. A key feature of ALD operation is the restoration of the substrate to its initial surface chemistry condition. Using this repeated set of steps, a film can be layered onto the substrate in equal metered layers that are all identical in chemical kinetics, deposition per cycle, composition, and thickness.

Self-saturating surface reactions make ALD insensitive to transport non-uniformities, which might otherwise impair surface uniformity, due either to engineering tolerances and the limitations of the flow process or related to surface topography (that is, deposition into three dimensional, high aspect ratio structures). As a general rule, a non-uniform flux of chemicals in a reactive process generally results in different completion times at different areas. However, with ALD, each of the reactions is allowed to complete on the entire substrate surface. Thus, differences in completion kinetics impose no penalty on uniformity. This is because the areas that are first to complete the reaction self-terminate the reaction; other areas are able to continue until the full treated surface undergoes the intended reaction.

Typically, an ALD process deposits about 0.1-0.2 nm of a film in a single ALD cycle (with numbered steps 1 through 4 as listed earlier). A useful and economically feasible cycle time must be achieved in order to provide a uniform film thickness in a range of about from 3 nm to 300 nm for many or most semiconductor applications, and even thicker films for other applications. Industry throughput standards dictate that substrates be processed in 2 minutes to 3 minutes, which means that ALD cycle times must be in a range from about 0.6 seconds to about 6 seconds.

An ALD process must be able to execute this sequencing efficiently and reliably for many cycles in order to allow cost-effective coating of many substrates. In an effort to minimize the time that an ALD reaction needs to reach self-termination, at any given reaction temperature, one approach has been to maximize the flux of chemicals flowing into the ALD reactor, using a so-called “pulsing” process. In the pulsed ALD process, a substrate sits in a chamber and is exposed to the above sequence of gases by allowing a first gas to enter the chamber, followed by a pumping cycle to remove that gas, followed by the introduction of a second gas to the chamber, followed by a pumping cycle to remove the second gas. This sequence can be repeated at any frequency and variations in gas type and/or concentration. The net effect is that the entire chamber experiences a variation in gas composition with time, and thus this type of ALD can be referred to as time dependent ALD. The vast majority of existing ALD processes are time dependent ALD.

Conventional ALD approaches include, for example, U.S. Pat. No. 6,821,563 entitled “GAS DISTRIBUTION SYSTEM FOR CYCLICAL LAYER DEPOSITION” to Yudovsky, hereby incorporated by reference, which describes a spatially dependent ALD processing system, under vacuum, having separate gas ports for precursor and purge gases, alternating with vacuum pump ports between each gas port. Each gas port directs its stream of gas vertically downward toward a substrate. The separate gas flows are separated by walls or partitions, with vacuum pumps for evacuating gas on both sides of each gas stream. The lower portions of the partitions are separated from the substrate surface by a distance sufficient to allow the gas streams to flow around the lower portions toward the vacuum ports after the gas streams react with the substrate surface.

In this embodiment, a rotary turntable or other transport device can be provided for holding one or more substrate wafers. With this arrangement, the substrate is shuttled beneath the different gas streams, effecting ALD deposition thereby. In one embodiment, the substrate is moved in a linear path through a chamber, in which the substrate is passed back and forth a number of times.

Another approach using a continuous gas flow spatially dependent ALD is shown in U.S. Pat. No. 4,413,022 entitled “METHOD FOR PERFORMING GROWTH OF COMPOUND THIN FILMS” to Suntola et al., hereby incorporated by reference. A gas flow array is provided with alternating source gas openings, carrier gas openings, and vacuum exhaust openings. Reciprocating motion of the substrate over the array effects ALD deposition, again, without the need for pulsed operation. In the embodiment of FIGS. 13 and 14 of Suntola et al., in particular, sequential interactions between a substrate surface and reactive vapors are made by a reciprocating motion of the substrate over a fixed array of source openings. Diffusion barriers are formed by a carrier gas opening between exhaust openings.

US Patent Publication No. 2005/0084610 to Selitser, hereby incorporated by reference, shows an atmospheric pressure atomic layer chemical vapor deposition process. Selitser et al. state that extraordinary increases in reaction rates are obtained by changing the operating pressure to atmospheric pressure, which will involve orders of magnitude increase in the concentration of reactants, with consequent enhancement of surface reactant rates. The embodiments of Selitser et al. involve separate chambers for each stage of the process, although FIG. 10 of Selitser shows an embodiment in which chamber walls are removed. A series of separated injectors are spaced around a rotating circular substrate holder track. Each injector incorporates independently operated reactant, purging, and exhaust gas manifolds and controls and acts as one complete mono-layer deposition and reactant purge cycle for each substrate as is passes there under in the process. The spacing of the injectors is selected so that cross-contamination from adjacent injectors is prevented by purging gas flows and exhaust manifolds incorporate in each injector.

A preferred embodiment of a spatially dependent ALD process for depositing a semiconductor thin film and optionally also a dielectric layer and a conductor layer in the present invention is described in detail in commonly assigned U.S. patent application Ser. No. 11/392,007, filed Mar. 29, 2006 by Levy et al. and entitled, “PROCESS FOR ATOMIC LAYER DEPOSITION;” U.S. patent application Ser. No. 11/392,006, filed Mar. 29, 2006 by Levy et al. and entitled “APPARATUS FOR ATOMIC LAYER DEPOSITION;” U.S. patent application Ser. No. 11/620,744, filed Jan. 8, 2007 by Levy and entitled “DEPOSITION SYSTEM AND METHOD USING A DELIVERY HEAD SEPARATED FROM A SUBSTRATE BY GAS PRESSURE;” and U.S. patent application Ser. No. 11/620,740, filed Jan. 8, 2007 by Nelson et al. and entitled “DELIVERY DEVICE COMPRISING GAS DIFFUSER FOR THIN FILM DEPOSITION.” All these identified applications are hereby incorporated by reference in their entirety. In particular, U.S. Ser. No. 11/392,007 employs a novel transverse flow pattern to prevent intermixing of the continuously flowing mutually reactive gases, while U.S. Ser. No. 11/620,744 and U.S. Ser. No. 11/620,740 employ a coating head partially levitated by the pressure of the reactive gases of the process to accomplish improved gas separation.

Zinc-oxide-based materials that can be made using such an atomic layer deposition process include, but are not limited to: ZnO, InZnO and InGaZnO. Doped materials that can be made include, for example, ZnO:Al, GaInZnO, MgₓZn₁₋ₓO, and LiZnO. It will be apparent to the skilled artisan that alloys of two, three or more metals may be deposited, compounds may be deposited with two, three or more constituents, and such things as graded films and nano-laminates may be produced as well.

For various volatile zinc-containing precursors, precursor combinations, and reactants useful in ALD thin film processes, reference is made to the Handbook of Thin Film Process Technology, Vol. 1, edited by Glocker and Shah, Institute of Physics (IOP) Publishing, Philadelphia 1995, pages B1.5:1 to B1.5:16, hereby incorporated by reference; and Handbook of Thin Film Materials, edited by Nalwa, Vol. 1, pages 103 to 159, hereby incorporated by reference, including Table V1.5.1 of the former reference.

In one particular embodiment, an ALD coating may have isolated channels through which flow: (1) inert nitrogen gas; (2) a mixture of nitrogen, air and water vapor; and (3) a mixture of active metal alkyl vapor (Me₃Al or Et₂Zn) in nitrogen. The flow rate of the active metal alkyl vapor can be controlled, for example, by bubbling nitrogen through the pure liquid (Me₃Al or Et₂Zn) contained in an airtight bubbler by means of individual mass flow control meters, and the flow of water vapor can be controlled by adjusting the bubbling rate of nitrogen passed through pure water in a bubbler.

Especially when employing an ALD technique for coating the semiconductor thin film, the resistivity of the ZnO can be enhanced by substitutional doping with an acceptor dopant made from a volatile organic compound, for example, volatile compounds comprising an acceptor dopant such as N, P, As, Li, Na, K, Cu, Ag, or mixtures thereof. Preferably, the acceptor dopant comprises a Group V element, more preferably nitrogen, for example, using an acceptor dopant precursor comprises nitrogen in the form of NO, N₂O, NO₂, or ammonia.

In order for such a gas to contain sufficient volatile materials to usefully affect the deposition process, the volatile compound must have a vapor pressure at room temperature of greater than 0.1 mm Hg, preferably greater than 1 mmHg. Such dopants are preferably present in the final semiconductor in the amount of 0.001% to 5%, more preferably 0.01% to 1%.

Another aspect of the present invention is the thin film transistor that can be made according to the above-described processes. Thus, the present invention includes thin film transistors in which in a passivation structure made from of developed photoresist material is in the shape of the gate structure and is located only over the semiconductor channel of the patterned semiconductor film.

In accordance with the above-described second embodiment, the thin film transistor comprises, in the same layer as the gate electrode, electrically isolated photomask patterns for fluid containment elements made of the same material as the gate structure. As a result, the thin film transistor has a passivation structure and opposed fluid containment elements, the latter aligned with the electrically isolated photomask patterns for fluid containment elements. The barriers can be in various shapes, including brackets that substantially enclose the source and drain.

In accordance with the above-described third embodiment, the thin film transistor comprises containment elements that form a substantially continuous barrier, in combination with the passivation structure, around the source and drain.

Electronic devices in which TFTs and other devices are useful include, for example, more complex circuits, e.g., shift registers, integrated circuits, logic circuits, smart cards, memory devices, radio-frequency identification tags, backplanes for active matrix displays, active-matrix displays (e.g. liquid crystal or OLED), solar cells, ring oscillators, and complementary circuits, such as inverter circuits, for example, in combination with other transistors made using available p-type organic semiconductor materials such as pentacene. In an active matrix display, a transistor made according to the present invention can be used as part of voltage hold circuitry of a pixel of the display. In such devices, the TFTs are operatively connected by means known in the art.

One example of a microelectronic device is an active-matrix liquid-crystal display (AMLCD). One such device is an optoelectronic display that includes elements having electrodes and an electro-optical material disposed between the electrodes. A connection electrode of the transparent transistor may be connected to an electrode of the display element, while the switching element and the display element overlap one another at least partly. An optoelectronic display element is here understood to be a display element whose optical properties change under the influence of an electrical quantity such as current or voltage such as, for example, an element usually referred to as liquid crystal display (LCD). The presently detailed transistor has sufficient current carrying capacity for switching the display element at such a high frequency that the use of the transistor as a switching element in a liquid crystal display is possible. The display element acts in electrical terms as a capacitor that is charged or discharged by the accompanying transistor. The optoelectronic display device may include many display elements each with its own transistor, for example, arranged in a matrix. Certain active matrix pixel designs, especially those supplying a display effect that is current driven, may require several transistors and other electrical components in the pixel circuit.

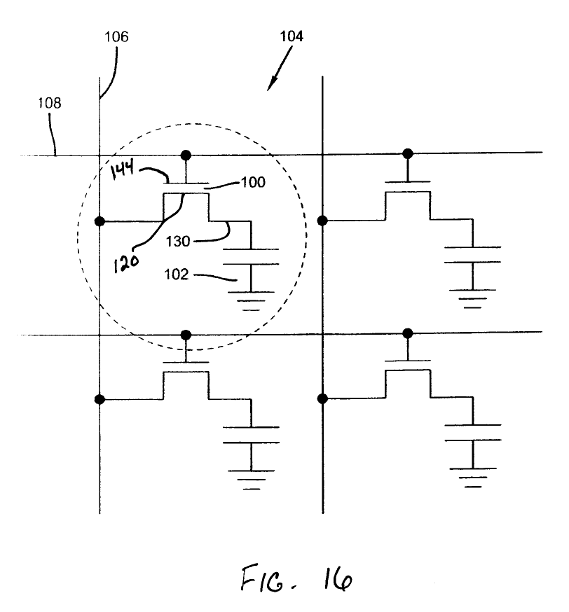

One specific example of a basic AMLCD cell circuit is depicted in FIG. 16. The AMLCD cell circuit includes a transistor 100 as presently described, and a LCD pixel 102 electrically coupled thereto. The transistor 100 and the LCD pixel 102 together form a transistor/pixel cell 104. In the arrangement shown, the transistor 100 is electrically coupled to the LCD pixel 102 via the drain electrode 130. The gate electrode 144 of the transistor 100 is electrically coupled to a row or control line 108 (also referred to as a select or gate line) that receives on/off input for the transistor 100. The source electrode 120 of the transistor 100 is electrically coupled to a column or data line 106 that receives a signal for controlling the LCD pixel 102. Each LCD pixel 102 can also be viewed as a capacitor representing the capacitance according to display design.

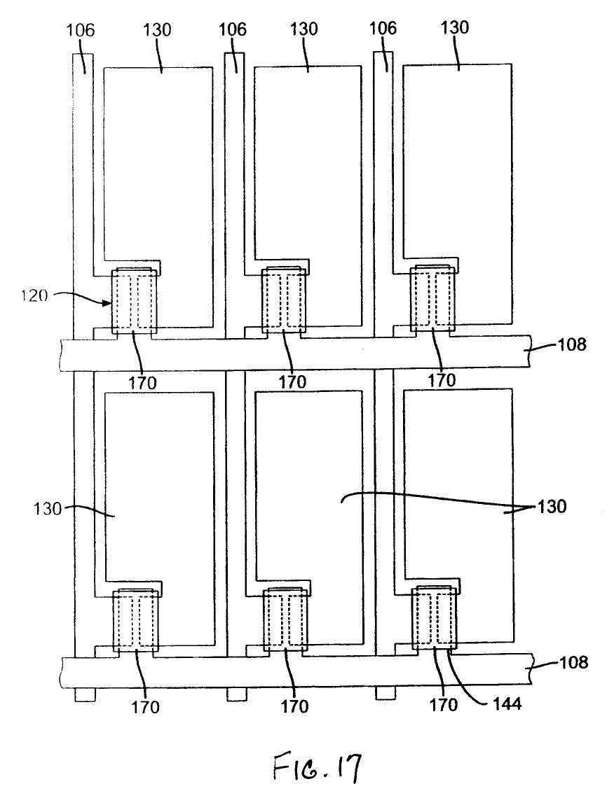

FIG. 17 shows a typical pixel layout in which data lines 106 lead to individual source electrodes 120, control lines 108 lead to individual gate electrodes 144, thin film transistors 170, and drain electrodes 130 each forming a pixel conductor pad.

Advantages of the invention will be demonstrated by the following examples, which are intended to be exemplary.

### EXAMPLES

### A. Semiconductor Layer Formation

A zinc-oxide-based nanoparticle layer was formulated as follows. All reagents were obtained from the Aldrich Chemical Company (Philadelphia). To a 40 mL amber glass bottle with screw cap was added 0.015 moles zinc acetate (99.99%) in 20 mL of methanol. With stirring, 270 μL of 18.5 MΩ water was added. The above solution was held, with stirring, at 60° C. in a constant temperature water bath for 10 minutes.

A solution of 7.68 mL of 2.93M KOH in methanol plus 4.32 mL of methanol was then added drop wise, at a rate of 1 mL/minute, to the above solution at 60° C. Following the completion of the base addition, the solution is kept stirring at 60° C. for 20 hours.

Following the completion of the reaction, 20 mL of the above solution were extracted and repeatedly washed by centrifugation followed by redispersion in methanol. The final wash consisted of redispersal in a solution of 1 part methanol and 3 parts hexanes, again followed by centrifugation. The final material was then redispersed in ethanol.

A typical sample of such a seed solution shows a primary particle size of approximately 80 nm as measured with UPA. The sample may also contain some particle aggregates of low number, leading to an apparent bimodal particle distribution. After washing, typical potassium content is less than a detection limit of less than 5 ppm as measured by inductively coupled plasma testing.

A coating solution was prepared by diluting the above nanoparticle formulation to 1.1% in ethanol. The above solution was applied to the substrate by spin coating at a rate of 2000 rpm. After the spin coating, the samples were annealed for 5 minutes at 200° C. in dry air. Following the annealing, a precursor layer consisting of zinc acetate dissolved in methanol at a concentration of 0.175M was spun on to the substrate at 2000 rpm. This layer was then annealed at 200° C. for 5 minutes in dry air.

### B. Device Measurement and Analysis

Electrical characterization of the fabricated devices was performed with a Hewlett Packard HP 4156 parameter analyzer. Device testing was done in air in a dark enclosure.

The results were averaged from several devices. For each device, the drain current (Id) was measured as a function of source-drain voltage (Vd) for various values of gate voltage (Vg). Furthermore, for each device the drain current was measured as a function of gate voltage for various values of source-drain voltage. For most devices, Vg was swept from −10 V to 40 V for each of the drain voltages measured, typically 5 V, 20 V, and 35 V, and 50 V. Mobility measurements were taken from the 35V sweep.

Parameters extracted from the data include field-effect mobility (μ), threshold voltage (Vth), subthreshold slope (S), and the ratio of Ion/Ioff for the measured drain current. The field-effect mobility was extracted in the saturation region, where Vd>Vg−Vth. In this region, the drain current is given by the equation (see Sze in Semiconductor Devices—Physics and Technology, John Wiley & Sons (1981)):

$${I}_{d} = \frac{W}{2 L} μ {{C}_{ox} ( {V}_{g} - {V}_{th} )}^{2}$$

where, W and L are the channel width and length, respectively, and Cₒₓ is the capacitance of the oxide layer, which is a function of oxide thickness and dielectric constant of the material. Given this equation, the saturation field-effect mobility was extracted from a straight-line fit to the linear portion of the √I_{d} versus Vg curve. The threshold voltage, Vₜₕ, is the x-intercept of this straight-line fit.

The log of the drain current as a function of gate voltage was plotted. Parameters extracted from the log I_{d} plot include the Iₒₙ/I_{off} ratio. The Iₒₙ/I_{off} ratio is simply the ratio of the maximum to minimum drain current, and S is the inverse of the slope of the I_{d} curve in the region over which the drain current is increasing (i.e., the device is turning on).

### Example 1

This Example illustrates the formation of a transistor, including S/D alignment with the gate, in accordance with one embodiment of the present invention. A 100 nm thick chromium gate pattern was deposited on a clean glass substrate using vacuum evaporation through a shadow mask, and then a 350 nm thick layer of SiNx dielectric was deposited by PECVD. The resulting substrate was stored in a clean environment until ready for use (FIGS. 2A, 2B). Prior to deposition of the semiconductor layer, this substrate washed for 10 minutes by treating with a solution of 70% sulfuric acid and 30% of a 30% solution of hydrogen peroxide maintained at approximately 100C. After washing, the semiconductor layer was prepared as described above. (The semiconductor layer was not patterned for present purposes of demonstrating of alignment feature.) The passivating film was prepared by spin coating at 4800 RPM for 60 seconds a 15-25% solution of a novolak resin activated with 3-10% of a naphthoquinone diazide ester derivative. The sample was heated for 60 seconds at 90° C. to remove residual solvent. The passivating film was exposed through the substrate using the chromium gate structure to mask the UV light, with unmasked regions receiving an exposure of 30 mW/cm² for 3.3 seconds. The exposed regions of the passivating film were removed from the substrate during a 45 second development in a solution of tetramethyl ammonium hydroxide, followed by a 15 second water rinse and spin dry. The resulting substrate contained a photopatterned passivation layer. A TENCOR profilometer was used to establish that the photopatterned passivation layer was approximately 1 μm thick and was aligned with the underlying gate metal pattern.

The resulting sample was placed in an inkjet printing system consisting of a sample platen supported by a set of x-y translation stages, piezoelectric demand-mode printheads supported by a z translation stage, and software to control these components. The printheads of this inkjet system dispense droplets in the 20-60 picoliter range. Approximately 2 cc of a commercially available silver nanoparticle ink purchased from Cabot Corporation was placed in a sample cartridge which was then screwed to the printing fixture. The printhead was primed with ink using pressurized nitrogen. The sample platen was heated to 70° C. Silver nanoparticle films were printed in the source and drain contact regions defined by the photopatterned passivation layer, heated for 30 minutes at 130° C. in air to form a conductive film with good electrical contact with the semiconducting layer. Optical micrographs clearly showed the silver source and drain electrodes were aligned to the gate pattern. Because the aligned passivating structure permanently remains over the TFT channel, ink ‘spillage’ on top of the passivator does not impact the TFT operation. Devices were tested for transistor activity as described below, indicating the saturation field-effect mobility for the zinc-oxide based semiconductor was 0.29 cm²/V-s.

### Example 2

In this example, TFT structures were prepared in identical fashion as in Example 1, with variations to illustrate the process flow for embodiment 3. A 100 nm thick aluminum gate pattern was deposited on a clean glass substrate using vacuum evaporation through a shadow mask, and then a 200 nm thick layer of aluminum oxide was deposited by sputter deposition. The semiconductor layer and passivating film was coated as described in Example 1. The passivating film was exposed according to FIGS. 10A, 10B, wherein during exposure a photomask containing a pattern of black stripes on a thin, flexible support was directly contacted with the back of the substrate. In this fashion, the passivating film was exposed to a composite pattern of UV light consisting of an overlay of the photomask and metal gate patterns. Unmasked regions received an exposure of 30 mW/cm² for 3.3 seconds. The remainder of the sample preparation procedure was identical to Example 1. Optical micrographs clearly showed the source and drain electrodes were aligned to the gate pattern, with a clearly defined channel width set by the patterned photomask, and with a clearly defined channel length set by the patterned gate. Because the aligned passivating structure permanently remains over the TFT channel, ink ‘spillage’ on top of the passivator does not impact the TFT channel length or width.

### Example 3

In this example, TFT structures were prepared using an atmospheric pressure ALD coating head to deposit an aluminum oxide dielectric film and the zinc oxide semiconductor film. The particular apparatus used to deposit these films has been described in more detail in U.S. application Ser. No. 11/392,006, filed Mar. 29, 2006 by Levy et al, and entitled “APPARATUS FOR ATOMIC LAYER DEPOSITION.” This coating head has isolated channels through which flow: (1) inert nitrogen gas; (2) a mixture of nitrogen and air vapor; and (3) a mixture of active metal alkyl vapor (Me₃Al or Et₂Zn) in nitrogen. The flow rate of the active metal alkyl vapor was controlled by bubbling nitrogen through the pure liquid contained in an airtight bubbler by means of individual mass flow control meters. The temperature of the coating head was maintained at 40° C. The flow rates of the individual gasses were adjusted to the settings shown in Table 1, below, and the coating process was initiated by oscillating the coating head across the substrate. The length of the reciprocation cycle was 32 mm. The rate of motion of the reciprocation cycle is 30 mm/sec.

TABLE 1

| | | | Metal | | | | | |
|---|---|---|---|---|---|---|---|---|
| | Me₃Al | Diethylzinc | Precursor | | Water | Oxidizer | Nitrogen | |
| | Bubbler | Bubbler | Dilution | Air | Bubbler | Dilution | Purge | |
| | Flow | Blow | Flow | Flow | Flow | Flow | Flow | |
| Layer | (sccm) | (sccm) | (sccm) | (sccm) | (sccm) | (sccm) | (sccm) | Cycles |
| Alumina film | 8 | 0 | 620 | 10 | 15 | 100 | 500 | 300 |
| ZnO film | 0 | 8 | 620 | 10 | 15 | 100 | 500 | 30 |

After deposition of the ALD films, the source and drain containment structure was prepared, and silver source and drain contacts were printed as described in Example 2. This procedure produced devices with a channel width of 480 micrometer and a channel length of 48 micrometer. Devices were tested for transistor activity as described above, indicating the saturation field-effect mobility for the zinc-oxide based semiconductor was 2.1 cm²/V-sec.

### PARTS LIST

1 substrate or support
3 gate electrode
5 gate-bus structure
7 bus line
9, 11 elongated sides of gate structure
13 terminal end side of gate structure
15 dielectric layer
17 continuous semiconductor film (patterned or unpatterned)
19 photoresist layer (partially patterned)
20 passivation layer
21 light rays
22, 23 outer containment elements
25 source
27 drain
32, 34 internal photomasks for outer containment elements
37 relatively low resolution photomask
39 masked portion of relatively low resolution photomask
100 transistor
102 LCD pixel
104 transistor/pixel cell
106 column or data line
108 row or control line
120 source electrode
130 drain electrode
144 ate electrode
170 thin film transistor
W width of semiconductor channel
L length of semiconductor channel

1. A method of making a transparent zinc-oxide-based thin film transistor supported on a substrate having a first side and a second side, wherein the substrate is substantially transmissive to a pre-selected spectrum of actinic radiation, the method comprising:
(a) depositing on the first side of the substrate a non-transmissive first conductive material to form a non-transmissive gate structure that is substantially not transmissive to the pre-selected spectrum of actinic radiation;
(b) depositing over the non-transmissive gate structure dielectric material to form a dielectric layer;
(c) depositing transparent zinc-oxide-based semiconductor material over the dielectric layer, vertically spaced from the non-transmissive gate structure by the dielectric layer;
(d) applying a layer of positive-working photoresist material over the first side of the substrate, over the semiconductor thin film, and then exposing the photoresist material to the pre-selected spectrum of actinic radiation from a source thereof through the second side of the substrate, wherein the non-transmissive gate structure masks the actinic radiation, thereby forming an exposed area of photoresist material not blocked by the non-transmissive gate structure;
(e) developing the exposed photoresist to form a patterned passivation structure comprising parallel elongated walls vertically aligned with parallel elongated sides of the non-transmissive gate structure;
(f) depositing a second conductive material to form a source electrode and a drain electrode, wherein the source electrode and the drain electrode are positioned over, and in electrical contact with, the semiconductor thin film and horizontally separated from each other by a spacing provided by the passivation structure; and
(g) patterning the transparent zinc-oxide semiconductor material to form a semiconductor thin film element in which the spacing provided by the passivation structure dimensionally defines a channel in the semiconductor thin film element that is aligned with the non-transmissive gate structure, wherein the semiconductor channel comprises parallel elongated sides that are aligned with the parallel elongated sides of the non-transmissive gate structure via the alignment with the elongated parallel walls of the passivation structure.

2. The method of claim 1 further comprising optionally removing the patterned passivation structure.

3. The method of claim 1 wherein the positive-working photoresist material is further patterned into one or more outer confinement elements that provide an outer horizontal boundary for the source electrode and/or the drain electrode, such that the source electrode and/or the drain electrode is formed between, or surrounded by, the parallel elongated walls of the passivation structure and the one or more outer confinement elements.

4. The method of claim 3 wherein the one or more outer confinement elements are formed by a relatively low resolution external mask, relative to channel, placed between the source of actinic radiation and the substrate simultaneously with forming the passivation structure.

5. The method of claim 3 where step (a) further comprises depositing the non-transmissive conductive material to also form non-transmissive internal photomasks, on either side of the non-transmissive gate structure and facing the non-transmissive gate structure, which internal photomasks are electrically isolated from the non-transmissive gate structure, such that the outer confinement elements are formed from the positive-working photoresist by the internal photomasks simultaneously with forming the passivation structure, and wherein the source electrode and/or the drain electrode are formed between the parallel elongated walls of the passivation structure and the outer confinement elements.

6. The method of claim 1 wherein (a) the photoresist material is sensitive to wavelength greater than 400 nm; (b) the substrate is substantially transparent to wavelength greater than 400 nm; and (c) the pre-selected spectrum of actinic radiation is wavelength greater than 400 nm.

7. The method of claim 1 wherein, in step (d), the layer of positive-working photoresist material is applied in a pattern so that there are regions covered by a layer of the photoresist material, including at least the channel, and regions not covered by the layer of photoresist material.

8. The method of claim 7 wherein the regions not covered by the layer of photoresist material includes regions over a bus line connected to other thin film transistors.

9. The method of claim 7 wherein the positive-working photoresist material is selectively applied over the semiconductor thin film to form said pattern, using an additive print process.

10. The method of claim 1 wherein, in step (d), the positive-working photoresist material is applied to the substrate without a pattern and then the layer of photoresist material is selectively exposed from the top side of the substrate using a mask.

11. The method of claim 1 wherein the photoresist material comprises an alkali-soluble novolac phenolic resin, a radiation-sensitive onium salt, and a spectral sensitizer, wherein the spectral sensitizer is matched to the transmittance spectrum of the substrate.

12. The method of claim 1 wherein the non-transmissive gate structure is deposited and patterned simultaneously by an additive method.

13. The method of claim 1 wherein the non-transmissive gate structure is deposited and patterned sequentially in a subtractive method.

14. The method of claim 1 wherein step (d) comprises exposing the substrate through the second side through a photomask located between the support and the substrate, wherein the developed photoresist material in step (e) further forms outer containment elements aligned with the photomask on one or both sides of the passivation structure.

15. The method of claim 1 wherein the gate structure forms a three-sided peninsula, diverging from a bus line, comprising parallel elongated sides which are perpendicular to the bus line and a terminal end that is substantially parallel to the bus line.

16. The method of claim 1 wherein the dielectric layer is unpatterned.

17. The method of claim 16 wherein the dielectric layer is composed of a material comprising Al₂O₃/TiO₂ or Al₂O₃.

18. The method of claim 1 wherein the semiconductor thin film is coated as a continuous layer and then patterned in step (g).

19. The method of claim 1, wherein the semiconductor material is deposited at a temperature under 300° C.

20. The method of claim 1 wherein the method comprises forming a semiconductor thin film by depositing over the substrate a colloidal solution of nanoparticles of the semiconductor material, wherein the nanoparticles are the reaction product of a mixture of reactants comprising an organometallic precursor compound and a basic ionic compound, and wherein the nanoparticles have an average primary particle size in the range of 10 to 150 nm and are colloidally stabilized in the colloidal solution.

21. The method of claim 1 wherein the method comprises forming a semiconductor thin film by chemical vapor deposition or atomic layer deposition comprising the reaction of a zinc-containing precursor with an oxidizing agent.

22. The method of claim 1 wherein the semiconductor thin film has a thickness of 10 to 150 nanometers.

23. The method of claim 1 wherein the material for the semiconductor thin film further comprises an acceptor dopant.

24. The method of claim 1 wherein the photoresist material is a phenol-formaldehyde polymer.

25. The method of claim 1 wherein the photoresist material is coated at a thickness of 0.05 microns to 5 microns.

26. The method of claim 1 wherein the source electrode and the drain electrode are made from metal or a conducting polymer.

27. The method of claim 1 wherein the gate structure comprises a material selected from doped silicon, metal, and conducting polymer.

28. The method of claim 1 wherein the source and the drain electrodes are formed from silver nanoparticles that are annealed at a temperature of 100° C. to 500° C., in order to convert to source and drain electrodes having a thickness of at least 500 Angstroms of substantially pure silver.

29. The method of claim 1 wherein the temperature of the substrate during the method is 100° C. or less.

30. The method of claim 1 wherein steps occur on a moving web substrate.

31. A plurality of thin film transistors according to claim 1 comprising a plurality of semiconductor thin film elements each over a gate structure, which gate structure is connected via a bus line to other gate structures, wherein a passivation structure of a photoresist material over the thin film element in each transistor is in a shape that is vertically aligned with the shape of a plurality of gate structures and the bus line connecting them, wherein the bus line is not continuous between pixels at the time of passivation patterning.

32. The thin film transistors of claim 31 wherein conductive material form non-transmissive internal photomasks, on either side of each gate structure and facing the gate structure, which internal photomasks are electrically isolated from the gate structure, such that outer confinement elements of the same photoresist material as the passivation structure are vertically aligned with the internal photomasks, and wherein the source electrode and/or the drain electrode are positioned between the elongated parallel walls of the passivation structure and the outer confinement elements.

33. The thin film transistor of claim 1, wherein the transistor has an on/off ratio of a source/drain current of at least 10⁴ and the transistor is configured for enhancement mode operation.

34. The thin film transistor of claim 1 wherein the semiconductor thin film exhibits a band gap of less than about 5 eV and a field effect electron mobility that is greater than 0.01 cm²/Vs.

35. An electronic device comprising a multiplicity of thin film transistors made according to claim 1.

36. The electronic device of claim 35 selected from the group consisting of an integrated circuit, active-matrix display, solar cell, flat panel display, active matrix imager, sensor, and rf label containing price, identification, and/or inventory information.

37. An optoelectronic display device comprising at least one display element coupled to a switch comprising an enhancement-mode, field effect transistor made according to claim 1.

38. The optoelectronic display device of claim 37, wherein the device comprises an active-matrix liquid-crystal display.
